(19) United States
(12) Patent Application Publication
(10) Pub. No.: US 2025/0244418 A1
(43) Pub. Date: Jul. 31, 2025

(54) MAGNETIC SENSOR

(71) Applicant: TDK Corporation, Tokyo (JP)

(72) Inventors: Takashi SAITO, Tokyo (JP); Hidekazu Kojima, Tokyo (JP); Hirokazu Takahashi, Tokyo (JP); Satoshi Miura, Tokyo (JP); Norikazu Ota, Tokyo (JP)

(73) Assignee: TDK Corporation, Tokyo (JP)

(21) Appl. No.: 19/033,856

(22) Filed: Jan. 22, 2025

(30) Foreign Application Priority Data
Jan. 31, 2024 (JP) 2024-013566

(51) Int. Cl. G01R 33/09

(52) U.S. Cl. CPC G01R 33/098; G01R 33/093

(57) ABSTRACT

A magnetic sensor includes an MR element, at least one yoke, and at least one magnetic field generator. The at least one yoke includes a magnetic layer made of a soft magnetic material, and is adjacent to the MR element and spaced at a distance apart from each other. The at least one magnetic field generator includes a ferromagnetic portion made of a ferromagnetic material and an antiferromagnetic portion made of an antiferromagnetic material and exchange-coupled with the ferromagnetic portion, and is configured to generate a magnetic field to be applied to the at least one yoke.

### CROSS REFERENCE TO RELATED APPLICATIONS

This application claims the benefit of Japanese Priority Patent Application No. 2024-13566 filed on Jan. 31, 2024, the entire contents of which are incorporated herein by reference.

### BACKGROUND

The disclosure relates to a magnetic sensor including a magnetoresistive element and yokes adjacent to the magnetoresistive element.

In recent years, magnetic sensors have been used for a variety of applications. Examples of known magnetic sensors include one that uses a spin-valve magnetoresistive element provided on a substrate. The spin-valve magnetoresistive element includes a magnetization pinned layer having a magnetization pinned in a certain direction, a free layer having a magnetization whose direction is variable depending on the direction of a target magnetic field, and a gap layer disposed between the magnetization pinned layer and the free layer.

Some magnetic sensors include a soft magnetic body that converges the magnetic field of the measurement target on the magnetoresistive element to improve the sensitivity of the magnetic sensor. In such magnetic sensors, a bias magnetic field generator that applies a bias magnetic field to a soft magnetic material is in some cases provided in order to reduce the hysteresis of the output signal.

Japanese Patent Application Laid-Open Publication No. 2018-194534 discloses a magnetic sensor including a magnetoresistive element, two magnetic convergence sections made of a soft magnetic material and disposed with the magnetoresistive element interposed therebetween, and two or four hard bias sections that apply a magnetic field to the two magnetic convergence sections.

Japanese Patent Application Laid-Open Publication No. 2022-038821 discloses a magnetic sensor including a magnetoresistive element, two yoke sections made of a soft magnetic material and disposed with the magnetoresistive element interposed therebetween, and two bias magnetic field generation sections that apply a magnetic field to the two yoke sections.

Magnetic sensors that use a bias magnetic field generation section made of a hard magnetic material as means of generating a bias magnetic field, as described in Japanese Patent Application Laid-Open Publication No. 2018-194534, have the following problem. Such magnetic sensors are usually used under the condition that the strength of the magnetic field to be detected does not exceed the coercivity of the hard magnetic material. However, since magnetic sensors can be used in a variety of environments, it can occur that an external magnetic field with a strength that exceeds the coercivity of the hard magnetic material is temporarily applied to the bias magnetic field generation section. If such an external magnetic field is temporarily applied to the bias magnetic field generation section, the direction of the magnetization of the bias magnetic field generation section may change from the initial direction, and may remain changed from the initial direction even after the external magnetic field disappears. In this case, the direction of the bias magnetic field changes from the desired direction.

### SUMMARY

A magnetic sensor according to one embodiment of the disclosure includes: a magnetoresistive element; at least one yoke including a magnetic layer made of a soft magnetic material, the at least one yoke being adjacent to the magnetoresistive element and spaced at a distance apart from each other; and at least one magnetic field generator including a ferromagnetic portion made of a ferromagnetic material and an antiferromagnetic portion made of an antiferromagnetic material and exchange-coupled with the ferromagnetic portion, the at least one magnetic field generator being configured to generate a magnetic field to be applied to the at least one yoke.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device including a magnetic sensor according to a first example embodiment of the disclosure.

FIG. 2 is a functional block diagram showing a configuration of the magnetic sensor device in the first example embodiment of the disclosure.

FIG. 3 is a circuit diagram showing a circuit configuration of the magnetic sensor according to the first example embodiment of the disclosure.

FIG. 4 is a perspective view showing a part of a first detection circuit in the first example embodiment of the disclosure.

FIG. 5 is a plan view showing a part of the first detection circuit in the first example embodiment of the disclosure.

FIG. 6 is a plan view showing a part of a second detection circuit in the first example embodiment of the disclosure.

FIG. 7 is a plan view showing a main part of the magnetic sensor according to the first example embodiment of the disclosure.

FIG. 8 is a plan view showing a magnetoresistive element, yokes, a magnetic field generator, and an insulating layer in the first example embodiment of the disclosure.

FIG. 9 is a cross-sectional view showing a part of a cross section at a position indicated by a 9-9 line in FIG. 7.

FIG. 10 is a cross-sectional view showing a part of a cross section at a position indicated by a 10-10 line in FIG. 7.

FIG. 11 is a cross-sectional view showing a part of a cross section at a position indicated by an 11-11 line in FIG. 7.

FIG. 12 is a plan view showing a main part of a first modification example of the magnetic sensor according to the first example embodiment of the disclosure.

FIG. 13 is a cross-sectional view showing a main part of a second modification example of the magnetic sensor according to the first example embodiment of the disclosure.

FIG. 14 is a cross-sectional view showing a main part of a third modification example of the magnetic sensor according to the first example embodiment of the disclosure.

FIG. 15 is a cross-sectional view showing a main part of a fourth modification example of the magnetic sensor according to the first example embodiment of the disclosure.

FIG. 16 is a cross-sectional view showing a main part of a fifth modification example of the magnetic sensor according to the first example embodiment of the disclosure.

FIG. 17 is a plan view showing a main part of a magnetic sensor according to a second example embodiment of the disclosure.

FIG. 18 is a cross-sectional view showing a part of a cross section at a position indicated by an 18-18 line in FIG. 17.

FIG. 19 is a cross-sectional view showing a part of a cross section at a position indicated by a 19-19 line in FIG. 17.

FIG. 20 is a cross-sectional view showing a part of a cross section at a position indicated by a 20-20 line in FIG. 17.

FIG. 21 is a cross-sectional view showing a main part of a first modification example of the magnetic sensor according to the second example embodiment of the disclosure.

FIG. 22 is a cross-sectional view showing a main part of a second modification example of the magnetic sensor according to the second example embodiment of the disclosure.

FIG. 23 is a cross-sectional view showing a main part of a third modification example of the magnetic sensor according to the second example embodiment of the disclosure.

FIG. 24 is a plan view showing a main part of a magnetic sensor according to a third example embodiment of the disclosure.

FIG. 25 is a cross-sectional view showing a part of a cross section at a position indicated by a 25-25 line in FIG. 24.

FIG. 26 is a cross-sectional view showing a part of a cross section at a position indicated by a 26-26 line in FIG. 24.

FIG. 27 is a plan view showing a main part of a magnetic sensor according to a fourth example embodiment of the disclosure.

FIG. 28 is a cross-sectional view showing a part of a cross section at a position indicated by a 28-28 line in FIG. 27.

FIG. 29 is a cross-sectional view showing a part of a cross section at a position indicated by a 29-29 line in FIG. 27.

FIG. 30 is a perspective view showing a magnetic sensor system including a magnetic sensor according to a fifth example embodiment of the disclosure.

FIG. 31 is a circuit diagram showing a circuit configuration of the magnetic sensor according to the fifth example embodiment of the disclosure.

FIG. 32 is a perspective view showing a part of the magnetic sensor according to the fifth example embodiment of the disclosure.

FIG. 33 is a plan view showing a part of the magnetic sensor according to the fifth example embodiment of the disclosure.

FIG. 34 is a side view showing a part of the magnetic sensor according to the fifth example embodiment of the disclosure.

### DETAILED DESCRIPTION

An object of the disclosure is to provide a magnetic sensor capable of applying a stable bias magnetic field to a yoke.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

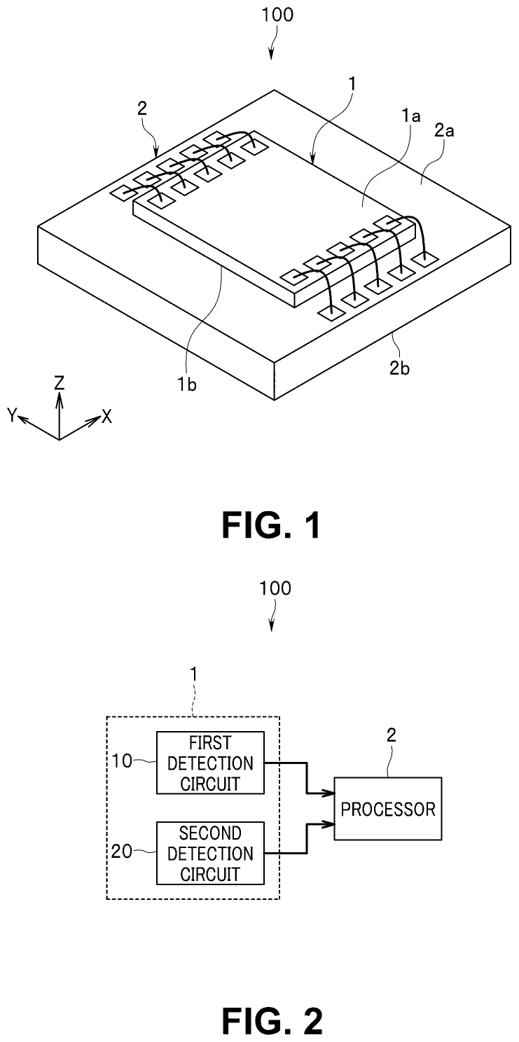

Initially, a configuration of a magnetic sensor device including a magnetic sensor according to a first example embodiment of the disclosure is described with reference to FIGS. 1 and 2. FIG. 1 is a perspective view showing the magnetic sensor device in the example embodiment. FIG. 2 is a functional block diagram showing a configuration of the magnetic sensor device in the example embodiment.

A magnetic sensor device 100 in the example embodiment includes a magnetic sensor 1 according to the example embodiment and a processor 2. The magnetic sensor 1 is configured to detect a target magnetic field, which is a magnetic field to be detected by the magnetic sensor 1, and to generate at least one detection signal. The magnetic sensor 1 may be a geomagnetic sensor that detects geomagnetism, a magnetic sensor for angle sensors or magnetic encoders that detects a rotating magnetic field, or a magnetic sensor for current sensors that detects a magnetic field generated by a current to be detected.

The processor 2 is configured to generate at least one detection value having a correspondence with the target magnetic field, based on at least one detection signal. The processor 2 is constituted, for example, by an application-specific integrated circuit (ASIC).

Each of the magnetic sensor 1 and the processor 2 is in a form of a chip having a rectangular parallelepiped shape. The magnetic sensor 1 includes a top surface 1a and a bottom surface 1b located on opposite sides of each other, and four side surfaces connecting the top surface 1a and the bottom surface 1b. The processor 2 includes a top surface 2a and a bottom surface 2b located on opposite sides of each other and four side surfaces connecting the top surface 2a and the bottom surface 2b. The magnetic sensor 1 is mounted on the top surface 2a of the processor 2 in such an orientation that the bottom surface 1b of the magnetic sensor 1 faces the top surface 2a of the processor 2. The magnetic sensor 1 is bonded to the processor 2 by adhesive, for example.

Here, X, Y, and Z directions are defined as shown in FIG. 1. The X, Y, and Z directions are orthogonal to one another. In the example embodiment, the Z direction is a direction perpendicular to the top surface 1a of the magnetic sensor 1 and from the bottom surface 1b of the magnetic sensor 1 to the top surface 1a . The directions opposite to the X, Y, and Z directions will be referred to as −X, −Y, and −Z directions, respectively.

Hereafter, the term “above” refers to positions located forward of a reference position in the Z direction, and “below” refers to positions located on a side of the reference position opposite from “above”. With respect to components of the magnetic sensor 1, the surface located at the end in the Z direction is referred to as “top surface,” and the surface located at the end in the −Z direction is referred to as “bottom surface. The expression “when viewed in a predetermined direction (e.g., the Z direction)” means that an object is viewed in a position away in the predetermined direction or in one direction parallel to the predetermined direction.

The magnetic sensor 1 includes a plurality of first pads (electrode pads) provided on the top surface 1a. The processor 2 includes a plurality of second pads (electrode pads) provided on the top surface 2a. In the magnetic sensor 1, of the plurality of first pads and the plurality of second pads, two corresponding pads are connected to each other by a bonding wire.

The magnetic sensor 1 includes a first detection circuit 10 and a second detection circuit 20. The first and second detection circuits 10 and 20 and the processor 2 are connected via the plurality of first pads, the plurality of second pads, and the plurality of bonding wires.

Each of the first and second detection circuits 10 and 20 includes a plurality of magnetic detection elements. In the example embodiment in particular, the plurality of magnetic detection elements are a plurality of magnetoresistive elements. The magnetoresistive elements will hereinafter be referred to as MR elements.

The first detection circuit 10 detects a component in a direction parallel to the X direction of the target magnetic field and generates at least one first detection signal having a correspondence with this component. The second detection circuit 20 detects a component in a direction parallel to the Y direction of the target magnetic field and generates at least one second detection signal having a correspondence with this component.

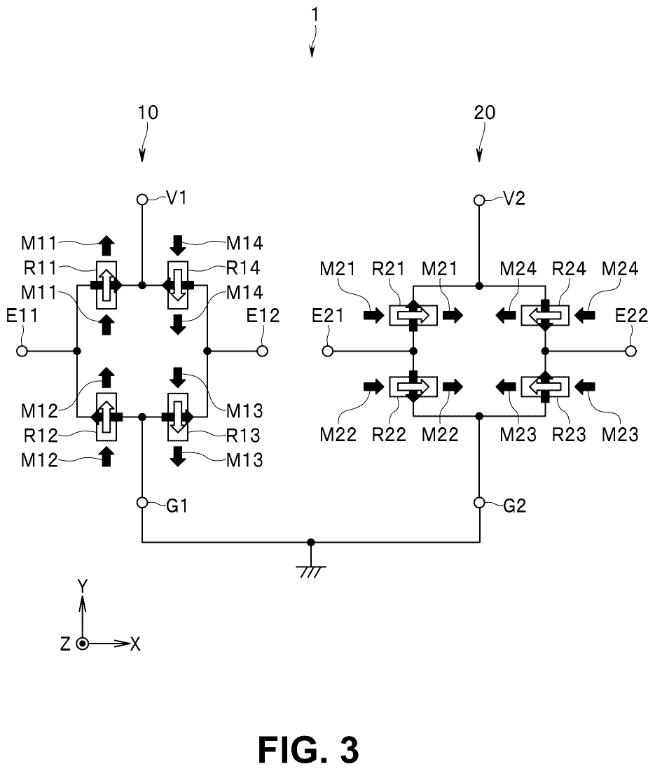

Next, a circuit configuration of the magnetic sensor 1 is described with reference to FIG. 3. FIG. 3 is a circuit diagram showing the circuit configuration of the magnetic sensor 1.

The first detection circuit 10 includes four resistor sections R11, R12, R13, and R14, a power supply port V1, a ground port G1, and two output ports E11 and E12. The resistor section R11 is provided between the power supply port V1 and the output port E11. The resistor section R12 is provided between the output port E11 and the ground port G1. The resistor section R13 is provided between the output port E12 and the ground port G1. The resistor section R14 is provided between the power supply port V1 and the output port E12. A voltage or current of a predetermined magnitude is applied to the power supply port V1. The ground port G1 is connected to ground.

The second detection circuit 20 includes four resistor sections R21, R22, R23, and R24, a power supply port V2, a ground port G2, and two output ports E21 and E22. The resistor section R21 is provided between the power supply port V2 and the output port E21. The resistor section R22 is provided between the output port E21 and the ground port G2. The resistor section R23 is provided between the output port E22 and the ground port G2. The resistor section R24 is provided between the power supply port V2 and the output port E22. A voltage or current of a predetermined magnitude is applied to the power supply port V2. The ground port G2 is connected to ground.

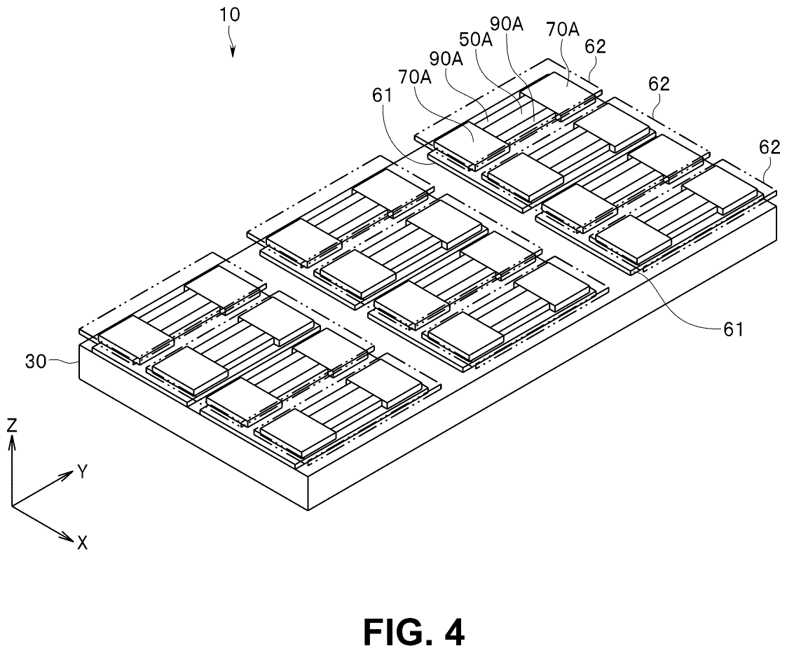

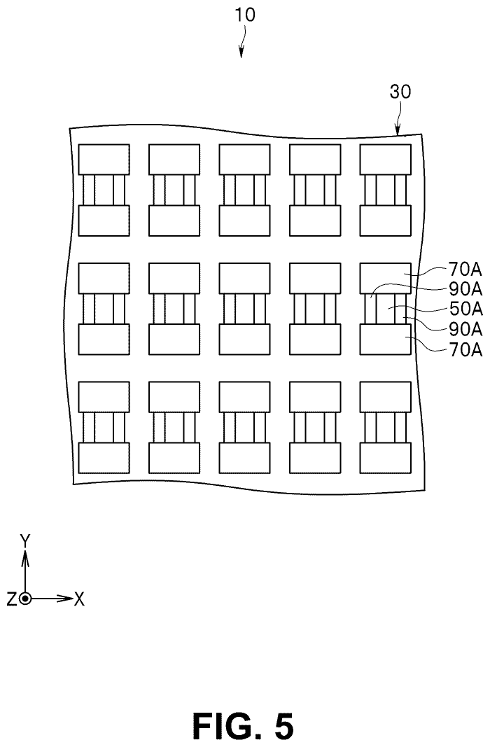

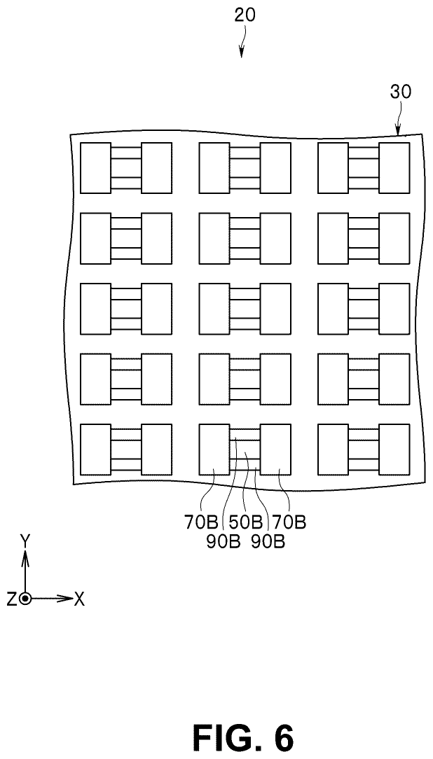

Next, respective configurations of the first and second detection circuits 10 and 20 will be described with reference to FIGS. 4 through 6. FIG. 4 is a perspective view showing a part of the first detection circuit 10. FIG. 5 is a plan view showing a part of the first detection circuit 10. FIG. 6 is a plan view showing a part of the second detection circuit 20.

The magnetic sensor 1 further includes a substrate 30. The magnetic sensor 1 is constituted by forming, on the substrate 30, a plurality of components other than the substrate 30. The first detection circuit 10 and the second detection circuit 20 are provided on the substrate 30. Each of the resistor sections R11 to R14 includes a plurality of MR elements 50A. Each of the resistor sections R21 to R24 includes a plurality of MR elements 50B.

Each of the resistor sections R11 to R14 may further include a plurality of lower electrodes 61 and a plurality of upper electrodes 62. As shown in FIGS. 4 and 5, each of the plurality of MR elements 50A has a shape long in a direction parallel to the Y direction. Each of the plurality of lower electrodes 61 electrically connects two adjacent MR elements 50A in a direction parallel to the X direction. Each of the plurality of upper electrodes 62 electrically connects the two adjacent MR elements 50A disposed on two lower electrodes 61. The plurality of MR elements 50A arranged in a row in a direction parallel to the X direction are thereby connected in series.

Each of the resistor sections R11 to R14 further includes a plurality of connecting electrodes (not shown). In each of the resistor sections R11 to R14, the plurality of connecting electrodes electrically connect the plurality of lower electrodes 61 or the plurality of upper electrodes 62 so that a group of the plurality of MR elements 50A arranged in a row is connected in series. With such a configuration, each of the resistor sections R11 to R14 includes the plurality of MR elements 50A connected in series by the plurality of lower electrodes 61, the plurality of upper electrodes 62, and the plurality of connecting electrodes.

The above description of the connection relationship of the plurality of MR elements 50A is basically applicable also to the plurality of MR elements 50B of each of the resistor sections R21 to R24. As shown in FIG. 6, in each of the resistor sections R21 to R24, each of the plurality of MR elements 50B has a shape long in a direction parallel to the X direction. In the above description of the connection relationship of the plurality of MR elements 50A, if the plurality of MR elements 50A, the X direction, and the Y direction are replaced with the plurality of MR elements 50B, the Y direction, and the X direction, respectively, a connection relationship of the plurality of MR elements 50B is described.

The magnetic sensor 1 further includes a plurality of yokes 90A and a plurality of yokes 90B, each including a magnetic layer made of a soft magnetic material. Soft magnetic materials used to form the magnetic layer include, for example, CoFe, CoNiFe, and NiFe.

The plurality of yokes 90A include a plurality of pairs of the yokes 90A, each pair including two yokes 90A. The two yokes 90A are disposed on both sides of one MR element 50A in a direction parallel to the X direction.

The plurality of yokes 90B include a plurality of pairs of the yokes 90B, each pair including two yokes 90B. The two yokes 90B are disposed on both sides of one MR element 50B in a direction parallel to the Y direction.

The magnetic sensor 1 further includes a plurality of magnetic field generators 70A and a plurality of magnetic field generators 70B. The plurality of magnetic field generators 70A include a plurality of pairs of the magnetic field generators 70A, each pair including two magnetic field generators 70A. The two magnetic field generators 70A are disposed at a distance from each other in a direction parallel to the Y direction with one MR element 50A and the two yokes 90A adjacent to the one MR element 50A interposed between the two magnetic field generators 70A. The two magnetic field generators 70A are configured to apply a bias magnetic field to the one MR element 50A and the two yokes 90A located between the two magnetic field generators 70A. This bias magnetic field includes a component parallel to the Y direction as a main component.

The plurality of magnetic field generators 70B include a plurality of pairs of the magnetic field generators 70B, each pair including two magnetic field generators 70B. The two magnetic field generators 70B are disposed at a distance from each other in a direction parallel to the X direction with one MR element 50B and the two yokes 90B adjacent to the one MR element 50B interposed between the two magnetic field generators 70B. The two magnetic field generators 70B are configured to apply a bias magnetic field to the one MR element 50B and the two yokes 90B located between the two magnetic field generators 70B. This bias magnetic field includes a component parallel to the X direction as the main component.

As shown in FIG. 4, each of the plurality of magnetic field generators 70A and each of the plurality of yokes 90A may be interposed between the lower electrode 61 and the upper electrode 62. Although not shown, each of the plurality of magnetic field generators 70B and each of the plurality of yokes 90B may be interposed between the lower electrode 61 and the upper electrode 62.

In the example embodiment, each of the plurality of MR elements 50A and each of the plurality of MR elements 50B is a spin-valve MR element. The spin-valve MR element includes a magnetization pinned layer having a magnetization pinned in a certain direction, a free layer having a magnetization whose direction is variable depending on the direction of the target magnetic field, and a gap layer disposed between the magnetization pinned layer and the free layer. The spin-valve MR element may be a TMR (tunnel magnetoresistive) element or may be a GMR (giant magnetoresistive) element. In the TMR element, the gap layer is a tunnel barrier layer. In the GMR element, the gap layer is a nonmagnetic conductive layer. The spin-valve MR element changes in resistance value depending on an angle that the direction of the magnetization of the free layer forms with respect to the direction of the magnetization of the magnetization pinned layer, and the resistance value is a minimum value when the angle is 0° and the resistance value is a maximum value when the angle is 180°. In each MR element, the free layer has shape anisotropy in which the direction of the magnetization easy axis is orthogonal to the direction of the magnetization of the magnetization pinned layer.

The spin-valve MR device may further include an antiferromagnetic layer. The antiferromagnetic layer is made of an antiferromagnetic material, and is in exchange coupling with the magnetization pinned layer to fix the direction of the magnetization of the magnetization pinned layer. The magnetization pinned layer may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. If the magnetization pinned layer is a self-pinned layer, the antiferromagnetic layer may be omitted.

Next, the direction of the magnetization of the magnetization pinned layer and the direction of the bias magnetic field will be described with reference to FIG. 3. In FIG. 3, a plurality of solid arrows drawn to overlap the resistor sections R11 to R14 and R21 to R24, respectively, represent the direction of the magnetization of the magnetization pinned layer in each of the resistor sections R11 to R14 and R21 to R24. In the example shown in FIG. 3, the direction of the main component of the magnetization of the magnetization pinned layer in each of the resistor sections R11 and R13 is the X direction. The direction of the main component of the magnetization of the magnetization pinned layer in each of the resistor sections R12 and R14 is the −X direction. The free layer in each of the resistor sections R11 to R14 has shape anisotropy in which the direction of the magnetization easy axis is a direction parallel to the Y direction.

The direction of the main component of the magnetization of the magnetization pinned layer in each of the resistor sections R21 and R23 is the Y direction. The direction of the main component of the magnetization of the magnetization pinned layer in each of the resistor sections R22 and R24 is the −Y direction. The free layer in each of the resistor sections R21 to R24 has shape anisotropy in which the direction of the magnetization easy axis is a direction parallel to the X direction.

In FIG. 3, arrows labelled with the reference numerals M11, M12, M13, and M14 indicate the directions of the main components of the bias magnetic fields generated by the plurality of magnetic field generators 70A of the resistor sections R11, R12, R13, and R14, respectively. The direction of the main component of the bias magnetic field at the resistor sections R11 and R12 is the Y direction. The direction of the main component of the bias magnetic field at the resistor sections R13 and R14 is the −Y direction.

In FIG. 3, the plurality of hollow arrows drawn to overlap the resistor sections R11 to R14, respectively, represent the direction of the magnetization of the free layer in each of the resistor sections R11 to R14 in a case where the target magnetic field is not applied to the magnetic sensor 1. The direction of the main component of the magnetization of the free layer in each of the resistor sections R11 and R12 is the Y direction, and is the same as the direction of the main component of the bias magnetic field at the resistor sections R11 and R12. The direction of the main component of the magnetization of the free layer in each of the resistor sections R13 and R14 is the −Y direction, and is the same as the direction of the main component of the bias magnetic field at the resistor sections R13 and R14.

In FIG. 3, arrows labelled with the reference numerals M21, M22, M23, and M24 indicate the directions of the main components of the bias magnetic fields generated by the plurality of magnetic field generators 70B of the resistor sections R21, R22, R23, and R24, respectively. The direction of the main component of the bias magnetic field at the resistor sections R21 and R22 is the X direction. The direction of the main component of the bias magnetic field at the resistor sections R23 and R24 is the −X direction.

In FIG. 3, the plurality of hollow arrows drawn to overlap the resistor sections R21 to R24, respectively, represent the direction of the magnetization of the free layer in each of the resistor sections R21 to R24 in a case where the target magnetic field is not applied to the magnetic sensor 1. The direction of the main component of the magnetization of the free layer in each of the resistor sections R21 and R22 is the X direction, and is the same as the direction of the main component of the bias magnetic field at the resistor sections R21 and R22. The direction of the main component of the magnetization of the free layer in each of the resistor sections R23 and R24 is the −X direction, and is the same as the direction of the main component of the bias magnetic field at the resistor sections R23 and R24.

Note that the direction of the magnetization may coincide with the direction of the main component of the magnetization mentioned above, or may deviate slightly from the direction of the main component of the magnetization. Similarly, the direction of the bias magnetic field may coincide with the direction of the main component of the bias magnetic field mentioned above, or may deviate slightly from the direction of the main component of the bias magnetic field. In the following description, the direction of the magnetization is assumed to coincide with the direction of the main component of the magnetization, and the direction of the bias magnetic field is assumed to coincide with the direction of the main component of the bias magnetic field.

Next, operations of the first and second detection circuits 10 and 20 will be described with reference to FIG. 3. In the first detection circuit 10, the potential of the connection point between the resistor sections R11 and R12, i.e., the potential of the output port E11, and the potential of the connection point between the resistor sections R13 and R14, i.e., the potential of the output port E12, change depending on the strength of the component in a direction parallel to the X direction of the target magnetic field. The first detection circuit 10 may generate a signal corresponding to the potential of the output port E11 and a signal corresponding to the potential of the output port E12, each as a first detection signal. Alternatively, the first detection circuit 10 may generate a signal corresponding to the potential difference between the output ports E11 and E12 as a first detection signal. In this case, the first detection circuit 10 may further include a differential amplifier (difference detector) that outputs the signal corresponding to the potential difference between the output ports E11 and E12 as the first detection signal.

In the second detection circuit 20, the potential of the connection point between the resistor sections R21 and R22, i.e., the potential of the output port E21, and the potential of the connection point between the resistor sections R23 and R24, i.e., the potential of the output port E22, change depending on the strength of the component in a direction parallel to the Y direction of the target magnetic field. The second detection circuit 20 may generate a signal corresponding to the potential of the output port E21 and a signal corresponding to the potential of the output port E22, each as a second detection signal. Alternatively, the second detection circuit 20 may generate a signal corresponding to the potential difference between the output ports E21 and E22 as a second detection signal. In this case, the second detection circuit 20 may further include a differential amplifier (difference detector) that outputs the signal corresponding to the potential difference between the output ports E21 and E22 as the second detection signal.

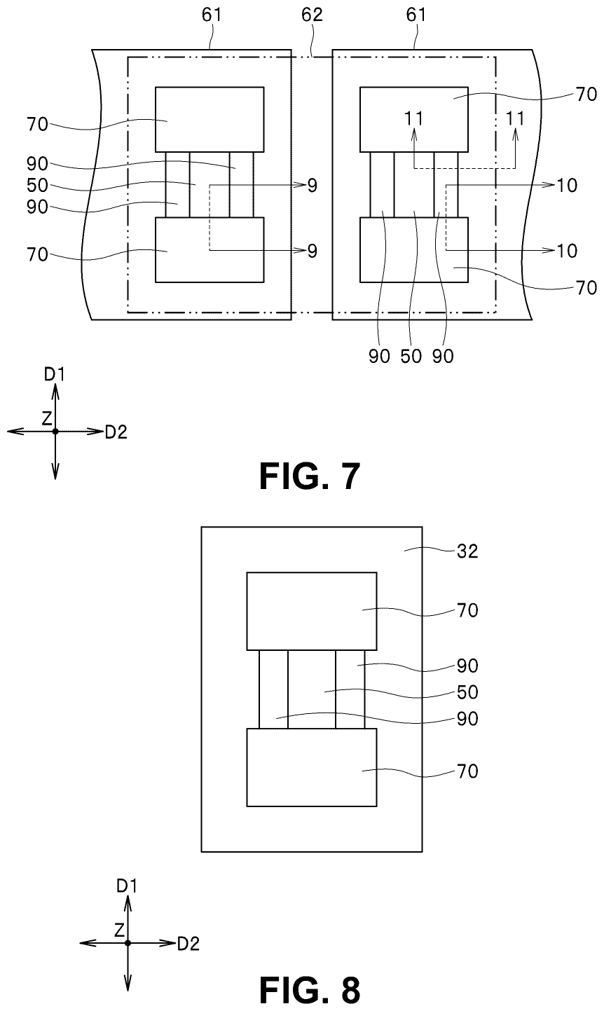

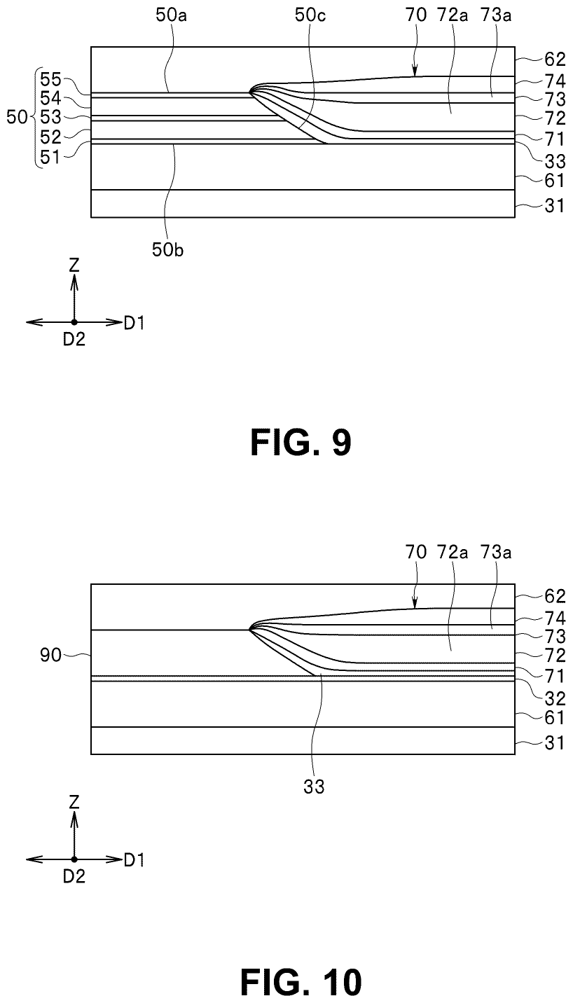

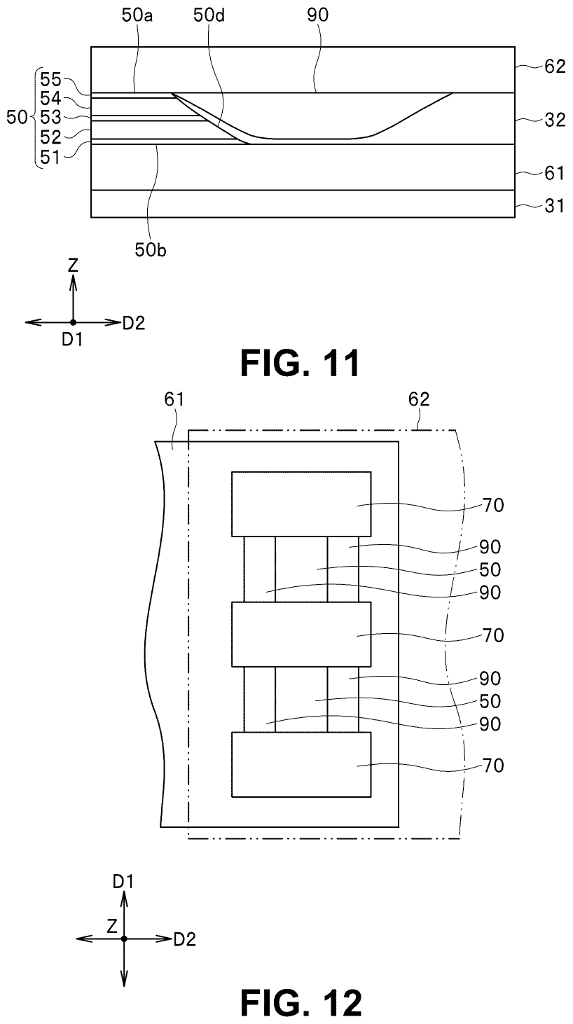

Next, configurations of the plurality of MR elements 50A, the plurality of MR elements 50B, the plurality of magnetic field generators 70A, the plurality of magnetic field generators 70B, the plurality of yokes 90A, and the plurality of yokes 90B will be described in detail with reference to FIGS. 7 through 11. FIG. 7 is a plan view showing a main part of the magnetic sensor 1. FIG. 8 is a plan view showing the MR element, the yokes, the magnetic field generators, and the insulating layer. FIG. 9 is a cross-sectional view showing a part of a cross section at a position indicated by a 9-9 line in FIG. 7. FIG. 10 is a cross-sectional view showing a part of a cross section at a position indicated by a 10-10 line in FIG. 7. FIG. 11 is a cross-sectional view showing a part of a cross section at a position indicated by an 11-11 line in FIG. 7.

Here, a first direction D1 and a second direction D2, which are each orthogonal to the Z direction and are orthogonal to each other, are defined as shown in FIGS. 7 through 11. In the first detection circuit 10, the first direction D1 is a direction parallel to the Y direction and the second direction D2 is a direction parallel to the X direction. In the second detection circuit 20, the first direction D1 is a direction parallel to the X direction and the second direction D2 is a direction parallel to the Y direction.

Hereinafter, any MR element of the plurality of MR elements 50A and the plurality of MR elements 50B will be denoted using the reference numeral 50, any magnetic field generator of the plurality of magnetic field generators 70A and the plurality of magnetic field generators 70B will be denoted using the reference numeral 70, and any yoke of the plurality of yokes 90A and the plurality of yokes 90B will be denoted using the reference numeral 90. The magnetic sensor 1 includes at least one MR element 50. In the example embodiment in particular, the magnetic sensor 1 includes a plurality of MR elements 50 as the at least one MR element 50.

Here, configurations of the MR element 50, the magnetic field generator 70, and the yoke 90 are described with a focus on one MR element 50. The MR element 50 includes a plurality of magnetic films. The stacking direction of the plurality of magnetic films is a direction parallel to the Z direction. The plurality of magnetic films include a magnetization pinned layer 52 and a free layer 54. Each of the plurality of MR elements 50 further includes a gap layer 53, a buffer layer 51, and a cap layer 55. As shown in FIGS. 9 and 10, the buffer layer 51, the magnetization pinned layer 52, the gap layer 53, the free layer 54, and the cap layer 55 are stacked in this order in the Z direction. Each of the buffer layer 51 and the cap layer 55 is formed of a nonmagnetic metallic material such as, for example, Ru, Ta, Cu, or Cr.

The MR element 50 includes a top surface 50a located at the end in the Z direction, a bottom surface 50b located at the end in the −Z direction, two side surfaces 50c located at both ends in the first direction D1, and two side surfaces 50d located at both ends in the second direction D2. The bottom surface 50b of the MR element 50 is in contact with the lower electrode 61. Each of the two side surfaces 50c and the two side surfaces 50d is inclined with respect to the stacking direction (a direction parallel to the Z direction) of the plurality of magnetic films.

The magnetic sensor 1 further includes at least one yoke 90 adjacent to the MR element 50 and spaced at a distance from each other. In the example embodiment in particular, the magnetic sensor 1 includes two yokes 90 disposed with the MR element 50 interposed between the two yokes 90. The MR element 50 is disposed between the two yokes 90 in the second direction D2.

The magnetic sensor 1 further includes an insulating layer 32 made of an insulating material such as Al₂O₃ or SiO₂ and disposed around the MR element 50. The two yokes 90 are embedded in the insulating layer 32. The insulating layer 32 is interposed between the MR element 50 and the two yokes 90 and between the lower electrode 61 and the two yokes 90. Each of the two yokes 90 is distanced from the MR element 50 by a thickness of the insulating layer 32 interposed between the MR element 50 and the two yokes 90.

Each of the two yokes 90 may include, in addition to the magnetic layer, a buffer layer interposed between the magnetic layer and the insulating layer 32, and a cap layer disposed on the magnetic layer. The buffer layer and the cap layer may be formed of a nonmagnetic metallic material such as, for example, Ru, Ta, Cu, or Cr.

Each of the two yokes 90 is disposed to ride up on the side surface 50d of the MR element 50. A part of each of the two yokes 90 overlaps a part of the MR element 50 when viewed in the Z direction.

The magnetic sensor 1 further includes at least one magnetic field generator 70 configured to generate a bias magnetic field to be applied to the two yokes 90. In the example embodiment in particular, the magnetic sensor 1 includes two magnetic field generators 70 disposed with the MR element 50 and the two yokes 90 interposed between the two magnetic field generators 70. The MR element 50 and the two yokes 90 are disposed between the two magnetic field generators 70 in the first direction D1. The insulating layer 32 is disposed also around the two magnetic field generators 70. The bias magnetic field generated by each of the two magnetic field generators 70 may also be applied to the MR element 50.

Each of the two magnetic field generators 70 is disposed to ride up on the side surface 50c of the MR element 50. A part of each of the two magnetic field generators 70 may overlap a part of the MR element 50 when viewed in the Z direction. Each of the two magnetic field generators 70 is disposed to ride up on each of the two yokes 90. A part of each of the two magnetic field generators 70 may overlap a part of each of the two yokes 90 when viewed in the Z direction.

Each of the two magnetic field generators 70 includes a ferromagnetic portion 72 made of a ferromagnetic material and an antiferromagnetic portion 73 made of an antiferromagnetic material. In the example embodiment in particular, the antiferromagnetic portion 73 is disposed on the ferromagnetic portion 72.

At least a part of each of the two magnetic field generators 70 overlaps the MR element 50 and the two yokes 90 when viewed in the first direction D1. In the example embodiment, the ferromagnetic portion 72 may include a ferromagnetic layer 72a made of a ferromagnetic material. The ferromagnetic layer 72a may be disposed to overlap the MR element 50 and the two yokes 90 when viewed in the first direction D1. The ferromagnetic layer 72a may be disposed to overlap the entirety of the free layer 54 when viewed in the first direction D1.

The ferromagnetic layer 72a is formed of a ferromagnetic material containing one or more elements selected from the group consisting of Co, Fe, and Ni. Examples of such a ferromagnetic material include CoFe, CoFeB, and CoNiFe.

Note that the ferromagnetic portion 72 may include, instead of the ferromagnetic layer 72a, a stack including a plurality of stacked ferromagnetic layers, in which two adjacent layers are made of ferromagnetic materials different from each other. Examples of such a stack include a stack of a Co layer, a CoFe layer, and a Co layer, and a stack of a Co₇₀Fe₃₀ layer, a Co₃₀Fe₇₀ layer, and a Co₇₀Fe₃₀ layer. Note that Co₇₀Fe₃₀ represents an alloy containing 70 atomic percent Co and 30 atomic percent Fe, and Co₃₀Fe₇₀ represents an alloy containing 30 atomic percent Co and 70 atomic percent Fe.

The antiferromagnetic portion 73 may include an antiferromagnetic layer 73a made of an antiferromagnetic material. The antiferromagnetic layer 73a is disposed on and in contact with the ferromagnetic layer 72a. The antiferromagnetic layer 73a is formed of an antiferromagnetic material such as, for example, IrMn or PtMn.

The ferromagnetic layer 72a has an overall magnetization. The overall magnetization of the ferromagnetic layer 72a is a volume average of the vector sum of magnetic moments for each unit of atoms, crystal lattices, etc. in the overall ferromagnetic layer 72a. Hereinafter, the overall magnetization of the ferromagnetic layer 72a is simply referred to as magnetization of the ferromagnetic layer 72a. The antiferromagnetic layer 73a is in contact with the top surface of the ferromagnetic layer 72a to be exchange-coupled with the ferromagnetic layer 72a. This defines the direction of the magnetization of the ferromagnetic layer 72a.

In the example embodiment, substantially the entirety of the ferromagnetic portion 72 is constituted by the ferromagnetic layer 72a, and substantially the entirety of the antiferromagnetic portion 73 is constituted by the antiferromagnetic layer 73a. The antiferromagnetic layer 73a is exchange-coupled with the ferromagnetic layer 72a, and thereby the antiferromagnetic portion 73 is exchange-coupled with the ferromagnetic portion 72. This defines the direction of the magnetization of the ferromagnetic portion 72. The direction of the magnetization of the ferromagnetic portion 72 coincides with the direction of the magnetization of the ferromagnetic layer 72a. The ferromagnetic portion 72 and the antiferromagnetic portion 73 generate a bias magnetic field based on the magnetization of the ferromagnetic portion 72. The magnetic field generator 70 thus constituted is highly resistant to disturbance magnetic fields.

The two magnetic field generators 70 cooperate to apply a bias magnetic field to the MR element 50 and the two yokes 90. The direction of the magnetization of the ferromagnetic portion 72 of one of the two magnetic field generators 70 may be the same as the direction of the magnetization of the ferromagnetic portion 72 of the other of the two magnetic field generators 70. In this case, the direction of the bias magnetic field generated by one of the two magnetic field generators 70 becomes the same as the direction of the bias magnetic field generated by the other of the two magnetic field generators 70.

Each of the two magnetic field generators 70 further includes a buffer layer 71 disposed on the bottom surface side (−Z direction side) of the ferromagnetic layer 72a and a cap layer 74 disposed on the antiferromagnetic layer 73a. Each of the buffer layer 71 and the cap layer 74 is formed of a nonmagnetic metallic material such as, for example, Ru, Ta, Cu, or Cr.

The magnetic sensor 1 further includes an insulating layer 31 made of an insulating material and interposed between the substrate 30 (see FIGS. 4 through 6) and the lower electrode 61, and an insulating layer 33 made of an insulating material and interposed between the MR element 50 and the two yokes 90, and the two magnetic field generators 70. The insulating layer 33 is further interposed between the two magnetic field generators 70 and the lower electrode 61. The insulating layers 31 and 33 are formed of an insulating material such as, for example, A₂O₃ or SiO₂.

The upper electrode 62 is disposed on the MR element 50, the two magnetic field generators 70, the two yokes 90, and the insulating layer 32. The top surface 50a of the MR element 50, and the top surface of each of the two magnetic field generators 70, i.e., the top surface of the cap layer 74 and the top surfaces of the two yokes 90, are in contact with the upper electrode 62. The magnetic sensor 1 further includes an insulating layer (not shown) made of an insulating material and disposed on the upper electrode 62.

Heretofore, the configurations of the MR element 50 and the magnetic field generator 70 have been described with a focus on one MR element 50. In the example embodiment, the magnetic sensor 1 includes the plurality of MR elements 50. Therefore, the magnetic sensor 1 includes a plurality of magnetic field generators 70 and a plurality of yokes 90.

Next, a method of forming the plurality of MR elements 50 in the example embodiment is described. In the process of forming the plurality of MR elements 50, a plurality of initial MR elements that later become the plurality of MR elements 50 are first formed. Each of the plurality of initial MR elements includes an initial magnetization pinned layer that later becomes a magnetization pinned layer 52, a buffer layer 51, a gap layer 53, a free layer 54, and a cap layer 55.

Next, the direction of the magnetization of the initial magnetization pinned layer is fixed in a predetermined direction by using laser light and an external magnetic field that contains a component in the predetermined direction. For example, in the plurality of initial MR elements that later become the plurality of MR elements 50A constituting the resistor sections R11 and R13 of the first detection circuit 10, the plurality of initial MR elements are irradiated with the laser light while applying an external magnetic field in the X direction to the plurality of initial MR elements. When the irradiation of the laser light is completed, the direction of the magnetization of the initial magnetization pinned layer is fixed in the X direction. This causes the initial magnetization pinned layer to become the magnetization pinned layer 52.

In the plurality of initial MR elements that later become the plurality of MR elements 50A constituting the resistor sections R12 and R14 of the first detection circuit 10, the direction of the magnetization of the initial magnetization pinned layer of each of the plurality of initial MR elements can be fixed in the −X direction by using an external magnetic field in the −X direction. The direction of the magnetization of the magnetization pinned layer 52 of each of a plurality of MR elements 50B constituting each of the resistor sections R21 to R24 of the second detection circuit 20 is also fixed by the same method as with the magnetization pinned layer 52 of each of the plurality of MR elements 50A.

The MR element 50 is completed by patterning the stacked film by etching so that two side surfaces 50c and two side surfaces 50d are formed on the stacked film after fixing the direction of the magnetization of the magnetization pinned layer 52.

Next, a method of forming the plurality of magnetic field generators 70 and the plurality of yokes 90 in the example embodiment will be described. Here, the method of forming the two magnetic field generators 70 and the two yokes 90 are described with a focus on one MR element 50. First, a first photoresist mask is formed on the stacked film that later becomes the MR element 50. Next, the stacked film is patterned by etching using the first photoresist mask so that the two side surfaces 50d (see FIG. 11) are formed on the stacked film. Next, while leaving the first photoresist mask in place, the insulating layer 32 (see FIGS. 8 and 11) is formed around the stacked film. Next, the first photoresist mask is removed.

Next, a second photoresist mask is formed on the stacked film and the insulating layer 32. Next, a second photoresist mask is used to form two groove portions to accommodate the two yokes 90 in the insulating layer 32. Next, while leaving the second photoresist mask in place, the two yokes 90 are formed in the two groove portions. Next, the second photoresist mask is removed. Note that before forming the two yokes 90, an insulating film (not shown) may be formed in the two groove portions.

Next, a third photoresist mask is formed on the stacked film, the two yokes 90, and the insulating layer 32. Next, the stacked film is patterned by etching so that the two side surfaces 50c (see FIG. 9) are formed on the stacked film. In this etching, the two yokes 90 and the insulating layer 32 are also etched. The formation of the two side surfaces 50c on the stacked film causes the stacked film to become the MR element 50. Next, while leaving the third photoresist mask in place, the insulating layer 33 and the two magnetic field generators 70 are formed in order. Next, the third photoresist mask is removed.

The process of forming the two magnetic field generators 70 includes a processes of forming in order a buffer layer 71, a ferromagnetic layer 72a, an antiferromagnetic layer 73a, and a cap layer 74, and a processes of fixing the direction of the magnetization of the ferromagnetic layer 72a. In the following, the process of fixing the direction of the magnetization of the ferromagnetic layer 72a is described in detail. The direction of the magnetization of the ferromagnetic layer 72a is fixed by the same method as with the magnetization pinned layer 52 of the MR element 50. In other words, after the cap layer 74 is formed first, the direction of the magnetization of the ferromagnetic layer 72a is fixed in a predetermined direction by using laser light and an external magnetic field including a component in the predetermined direction. For example, for the plurality of magnetic field generators 70 disposed near the plurality of MR elements 50A that later constitute the resistor sections R11 and R12 of the first detection circuit 10, respectively, the plurality of magnetic field generators 70 are irradiated with the laser light while applying an external magnetic field in the Y direction to the plurality of magnetic field generators 70. When the irradiation of the laser light is completed, the direction of the magnetization of the ferromagnetic layer 72a of each of the plurality of magnetic field generators 70 is fixed in the Y direction.

For the plurality of magnetic field generators 70 disposed near the plurality of MR elements 50A that later constitute the resistor sections R13 and R14 of the first detection circuit 10, respectively, an external magnetic field in the −Y direction can be used to fix the direction of the magnetization of the ferromagnetic layer 72a of each of the plurality of magnetic field generators 70 in the −Y direction. Also for the ferromagnetic layer 72a of each of the plurality of magnetic field generators 70 disposed near the plurality of MR elements 50B that constitute each of the resistor sections R21 to R24 of the second detection circuit 20, the direction of the magnetization is fixed by the same method as mentioned above.

Note that the intensity of the laser light used to fix the direction of the magnetization of the ferromagnetic layer 72a may be smaller than the intensity of the laser light used to fix the direction of the magnetization of the magnetization pinned layer 52. The intensity of the laser light used to fix the direction of the magnetization of the ferromagnetic layer 72a may be an intensity such that the change in magnetoresistive change rate, which is the ratio of the magnetoresistive change to the resistance of the MR element 50, is restrained.

Next, an operation and an effect of the magnetic sensor 1 according to the example embodiment will be described. The magnetic sensor 1 according to the example embodiment includes the MR element 50 and the two yokes 90 adjacent to the MR element 50 and spaced at a distance from each other. Depending on the use environment of the magnetic sensor 1, it can occur that a high-strength disturbance magnetic field may temporarily be applied to the magnetic sensor 1. In this case, the two yokes 90 are magnetized in a predetermined direction depending on the direction of the disturbance magnetic field. As a result, the output signal of the magnetic sensor 1 may change in a case where the target magnetic field is not applied to the magnetic sensor 1.

In contrast, the magnetic sensor 1 according to the example embodiment further includes two magnetic field generators 70 configured to generate a bias magnetic field to be applied to the two yokes 90. According to the example embodiment, the bias magnetic field enables to align the directions of the magnetizations of the two yokes 90 in a predetermined direction, enabling to restrain the change of the output signal of the magnetic sensor 1 in a case where no target magnetic field is applied to the magnetic sensor 1.

In the example embodiment in particular, each of the two magnetic field generators 70 includes the ferromagnetic portion 72 and the antiferromagnetic portion 73 that is exchange-coupled with the ferromagnetic portion 72. The magnetic field generator 70 thus constituted is highly resistant to disturbance magnetic fields compared to a magnetic body made of a hard magnetic material such as a magnet. Accordingly, according to the example embodiment, it is enabled to more effectively restrain the change of the output signal of the magnetic sensor 1 in a case where the target magnetic field is not being applied to the magnetic sensor 1.

### Modification Examples

Next, first through fifth modification examples of the magnetic sensor 1 according to the example embodiment will be described. Initially, the first modification example is described with reference to FIG. 12. FIG. 12 is a plan view showing a main part of the first modification example of the magnetic sensor 1.

In the first modification example, two MR elements 50, three magnetic field generators 70, and four yokes 90 are disposed between the lower electrode 61 and the upper electrode 62. Here, “first”, “second”, and “third” are used to distinguish the three magnetic field generators 70 from one another. The first magnetic field generator 70 is disposed between the two MR elements 50 arranged along the first direction D1. The second magnetic field generator 70 is disposed at a position where one of the two MR elements 50 is disposed between the second magnetic field generator 70 and the first magnetic field generator 70. The third magnetic field generator 70 is disposed at a position where the other of the two MR elements 50 is disposed between the third magnetic field generator 70 and the first magnetic field generator 70.

The two yokes 90 are disposed between the first magnetic field generator 70 and the second magnetic field generator 70. Other two yokes 90 are disposed between the first magnetic field generator 70 and the third magnetic field generator 70.

The two MR elements 50 shown in FIG. 12 are connected to the same lower electrode 61 and the same upper electrode 62. The two 50 MR elements are connected in parallel in circuit configuration. Here, the two MR elements 50 connected in parallel in circuit configuration is referred to as an element pair. Each of the plurality of lower electrodes 61 electrically connects two adjacent element pairs in the second direction D2. Each of the plurality of upper electrodes 62 electrically connects two adjacent element pairs disposed on the two lower electrodes 61. This connects in series a plurality of element pairs arranged in a row in the second direction D2.

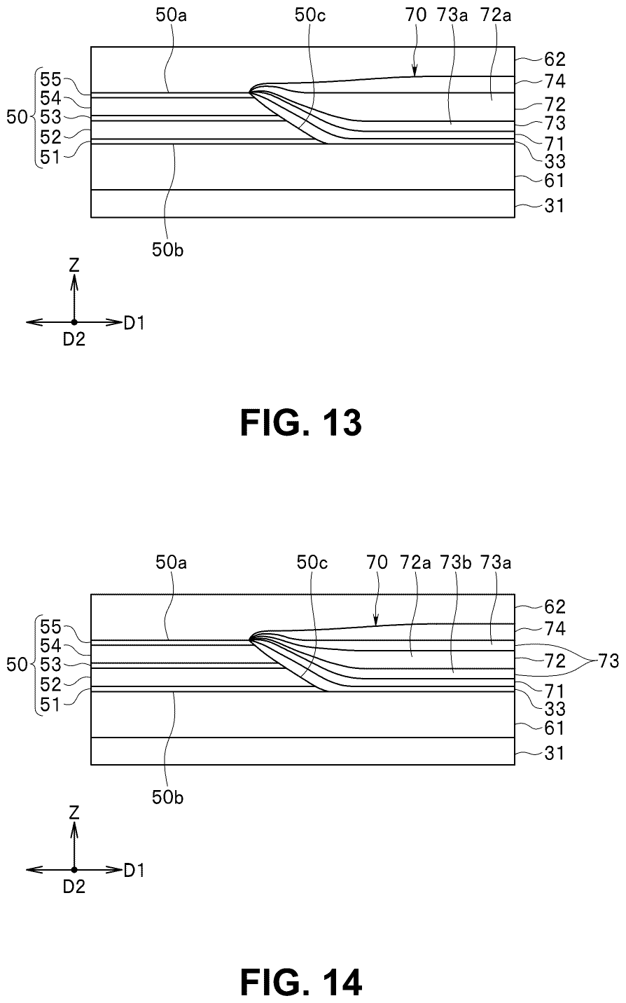

Next, the second modification example is described with reference to FIG. 13. FIG. 13 is a cross-sectional view showing a main part of the second modification example of the magnetic sensor 1. In the second modification example, the antiferromagnetic layer 73a, the ferromagnetic layer 72a, and the cap layer 74 are disposed in order on the buffer layer 71. In the second modification example, the antiferromagnetic layer 73a is in contact with the bottom surface of the ferromagnetic layer 72a to be exchange-coupled with the ferromagnetic layer 72a. This defines the direction of the magnetization of the ferromagnetic layer 72a.

Next, the third modification example is described with reference to FIG. 14. FIG. 14 is a cross-sectional view showing a main part of the third modification example of the magnetic sensor 1. In the third modification example, the antiferromagnetic portion 73 includes an antiferromagnetic layer 73b in addition to the antiferromagnetic layer 73a. The antiferromagnetic layer 73b is disposed between the buffer layer 71 and the ferromagnetic layer 72a. The antiferromagnetic layer 73b is formed of an antiferromagnetic material such as, for example, IrMn or PtMn.

The antiferromagnetic layer 73b is in contact with the bottom surface of the ferromagnetic layer 72a to be exchange-coupled with the ferromagnetic layer 72a. As previously mentioned, the antiferromagnetic layer 73a is in contact with the top surface of the ferromagnetic layer 72a to be exchange-coupled with the ferromagnetic layer 72a. In the third modification example, the antiferromagnetic layer 73a and the antiferromagnetic layer 73b are exchange-coupled with the ferromagnetic layer 72a, to define the direction of the magnetization of the ferromagnetic layer 72a.

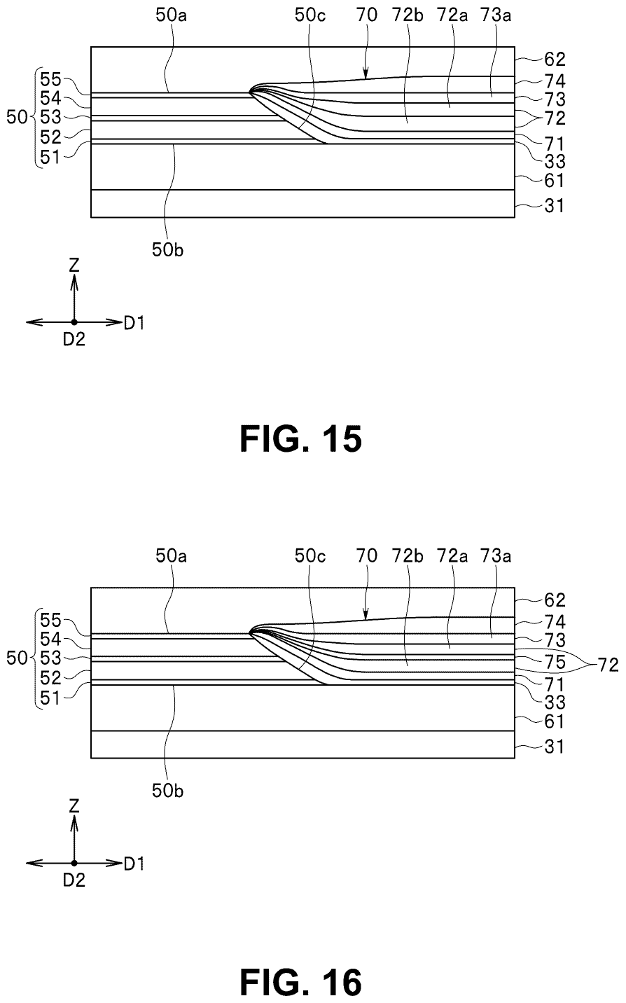

Next, the fourth modification example is described with reference to FIG. 15. FIG. 15 is a cross-sectional view showing a main part of the fourth modification example of the magnetic sensor 1. In the fourth modification example, the ferromagnetic portion 72 includes a ferromagnetic layer 72b in addition to the ferromagnetic layer 72a. The ferromagnetic layer 72b is disposed between the buffer layer 71 and the ferromagnetic layer 72a. The ferromagnetic layer 72b is formed of a ferromagnetic material containing one or more elements selected from the group consisting of Co, Fe, and Ni. In the fourth modification example, the ferromagnetic layer 72b has a magnetization in the same direction as the magnetization of the ferromagnetic layer 72a.

In the fourth modification example, the ferromagnetic layer 72a may be formed of a ferromagnetic material capable of increasing the exchange coupling energy with the antiferromagnetic layer 73a, and the ferromagnetic layer 72b may be formed of a ferromagnetic material having a saturation magnetic flux density larger than that of the ferromagnetic material constituting the ferromagnetic layer 72a. In this case, the strength of the bias magnetic field generated by the magnetic field generator 70 can be increased while increasing the exchange coupling energy between the ferromagnetic portion 72 including the ferromagnetic layers 72a and 72b and the antiferromagnetic layer 73a, and the magnetic field generator 70 can be made smaller. Examples of the ferromagnetic layer 72a include a Co₇₀Fe₃₀ layer. Examples of the ferromagnetic layer 72b include a Co₃₀Fe₇₀ layer.

Next, the fifth modification example is described with reference to FIG. 16. FIG. 16 is a cross-sectional view showing a main part of the fifth modification example of the magnetic sensor 1. In the fifth modification example, the ferromagnetic portion 72 includes a ferromagnetic layer 72b in addition to the ferromagnetic layer 72a. The ferromagnetic layer 72b is disposed between the buffer layer 71 and the ferromagnetic layer 72a. The ferromagnetic layer 72b is formed of a ferromagnetic material containing one or more elements selected from the group consisting of Co, Fe, and Ni. The ferromagnetic layer 72a and the ferromagnetic layer 72b may be formed of a same ferromagnetic material or different ferromagnetic materials.

In the fifth modification example, the magnetic field generator 70 further includes a nonmagnetic layer 75 disposed between the ferromagnetic layer 72a and the ferromagnetic layer 72b. The nonmagnetic layer 75 is formed of a nonmagnetic metallic material such as, for example, Ru.

In the fifth modification example, the ferromagnetic layer 72a and the ferromagnetic layer 72b are ferromagnetically exchange-coupled with each other via the nonmagnetic layer 75 so as to have the same magnetization direction. The ferromagnetic layer 72a and the ferromagnetic layer 72b have a magnetization in the same direction. The thickness of the nonmagnetic layer 75 is set to a thickness such that the exchange coupling between the ferromagnetic layer 72a and the ferromagnetic layer 72b is not lost.

### Second Example Embodiment

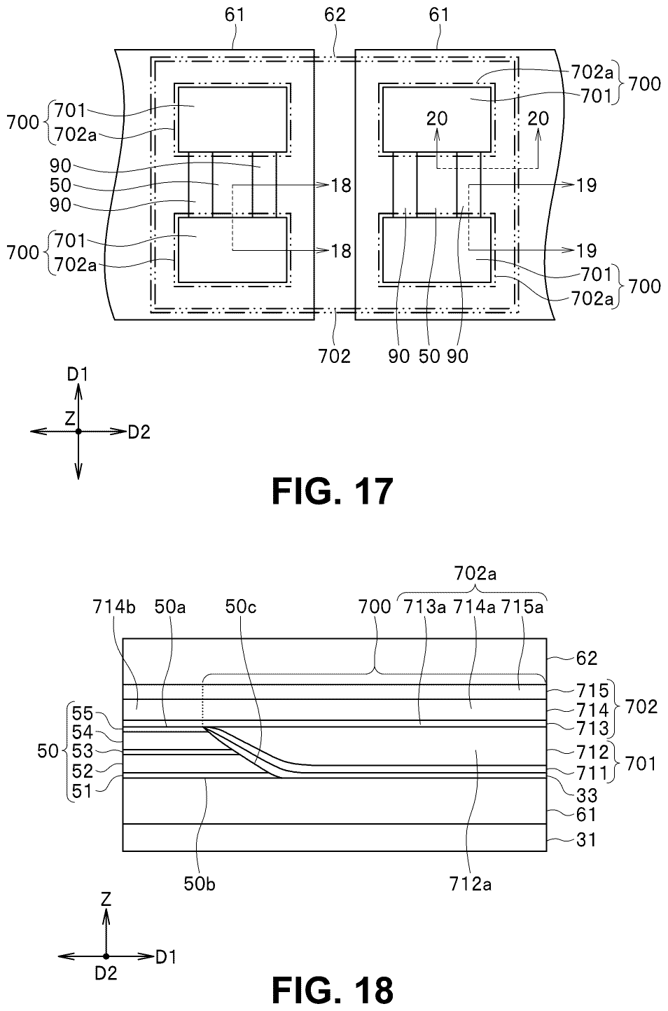

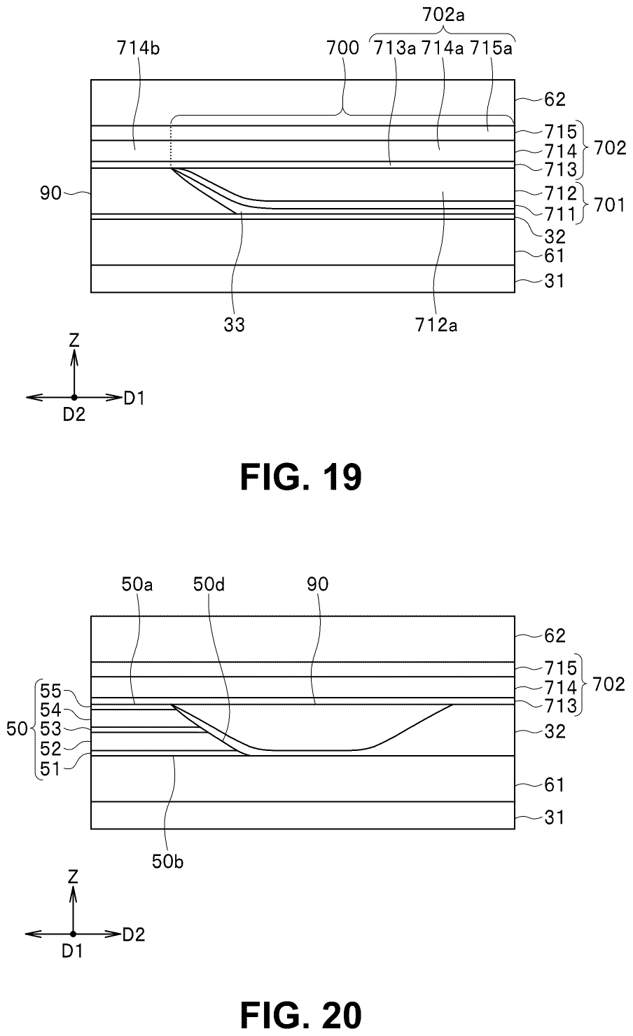

Next, a second example embodiment of the disclosure is described with reference to FIGS. 17 through 20. FIG. 17 is a plan view showing a main part of a magnetic sensor according to the example embodiment. FIG. 18 is a cross-sectional view showing a part of a cross section at a position indicated by an 18-18 line in FIG. 17. FIG. 19 is a cross-sectional view showing a part of a cross section at a position indicated by a 19-19 line in FIG. 17. FIG. 20 is a cross-sectional view showing a part of a cross section at a position indicated by a 20-20 line in FIG. 17.

The magnetic sensor 1 according to the example embodiment includes a plurality of magnetic field generators 700 instead of the plurality of magnetic field generators 70 in the first example embodiment. The function of the plurality of magnetic field generators 700 and the positional relationship of the plurality of magnetic field generators 700 with respect to the plurality of MR elements 50 and the plurality of yokes 90 are the same as those in the first example embodiment.

Hereinafter, a configuration of the magnetic field generator 700 is described with a focus on one MR element 50. The magnetic sensor 1 according to the example embodiment includes two magnetic field generators 700 disposed with the MR element 50 and the two yokes 90 interposed between the two magnetic field generators 700. Each of the two magnetic field generators 700 includes a ferromagnetic portion 712 made of a ferromagnetic material.

The ferromagnetic portion 712 includes a ferromagnetic layer 712a made of a ferromagnetic material. The ferromagnetic layer 712a is disposed to overlap the MR element 50 and the two yokes 90 when viewed in the first direction D1. In the example embodiment in particular, the ferromagnetic layer 712a is disposed to overlap the entirety of the free layer 54 when viewed in the first direction D1. The MR element 50 is disposed between two ferromagnetic layers 712a disposed at a distance from each other in the first direction D1. The ferromagnetic layer 712a may be formed of, for example, the same material as of the ferromagnetic layer 72a in the first example embodiment.

Each of the two magnetic field generators 700 further includes a buffer layer 711 disposed on the bottom surface side of the ferromagnetic portion 712. The buffer layer 711 may be formed of, for example, the same material as of the buffer layer 71 in the first example embodiment.

The magnetic sensor 1 according to the example embodiment may further include an underlying layer 713 disposed on the MR element 50, the two ferromagnetic layers 712a, the two yokes 90, and the insulating layer 32, an antiferromagnetic layer 714 disposed on the underlying layer 713, and a cap layer 715 disposed on the antiferromagnetic layer 714. The antiferromagnetic layer 714 may include two facing parts 714a that respectively face the two ferromagnetic layers 712a via the underlying layer 713, and a non-facing part 714b that faces the MR element 50, the two yokes 90, and the insulating layer 32 via the underlying layer 713 but does not face the two ferromagnetic layers 712a. The two facing parts 714a are connected to each other by the non-facing part 714b.

The underlying layer 713 includes two interposing portions 713a interposed between the two ferromagnetic layers 712a and the two facing parts 714a. The cap layer 715 includes two protective portions 715a disposed on the two facing parts 714a.

The underlying layer 713 is formed of a metallic material. In the example embodiment in particular, the underlying layer 713 is formed of a ferromagnetic metallic material. If the underlying layer 713 is formed of a ferromagnetic metallic material, the underlying layer 713 may be formed of the same material as of the ferromagnetic layer 712a. Note that in the underlying layer 713, at least the interposing portion 713a may have magnetism. The part of the underlying layer 713 that is interposed between the MR element 50, the two yokes 90, and the insulating layer 32, and the antiferromagnetic layer 714 may or may not have magnetism.

The antiferromagnetic layer 714 may be formed of, for example, a material same as of the antiferromagnetic layer 73a in the first example embodiment. The cap layer 715 may be formed of, for example, a material same as of the cap layer 74 in the first example embodiment.

The buffer layer 711 and the ferromagnetic layer 712a constitute a first stack 701. The underlying layer 713, the antiferromagnetic layer 714, and the cap layer 715 constitute a second stack 702. The MR element 50 is disposed between the two first stacks 701. The second stack 702 is disposed on the MR element 50, the two yokes 90, the insulating layer 32, and the two first stacks 701.

The second stack 702 includes two stacked parts 702a disposed on the two first stacks 701. Each of the two stacked parts 702a may include the interposing portion 713a, the facing part 714a, and the protective portion 715a.

In a stack including the first stack 701 and the stacked part 702a disposed on the first stack 701, the facing part 714a is exchange-coupled with the ferromagnetic layer 712a. This defines the direction of the magnetization of the ferromagnetic layer 712a.

Each of the two magnetic field generators 700 further includes an antiferromagnetic portion made of an antiferromagnetic material. In the example embodiment, substantially the entirety of the antiferromagnetic portion is constituted of the facing part 714a. In the example embodiment, substantially the entirety of the ferromagnetic portion 712 is constituted of the ferromagnetic layer 712a. The facing part 714a is exchange-coupled with the ferromagnetic layer 712a, and thereby the antiferromagnetic portion is exchange-coupled with the ferromagnetic portion 712. This defines the direction of the magnetization of the ferromagnetic portion 712. The direction of the magnetization of the ferromagnetic portion 712 coincides with the direction of the magnetization of the ferromagnetic layer 712a. The ferromagnetic portion 712 and the antiferromagnetic portion generate a bias magnetic field based on the magnetization of the ferromagnetic portion 712. The bias magnetic field is applied to the MR element 50 and the two yokes 90.

Since the ferromagnetic layer 712a is a part of the first stack 701 and the facing part 714a is a part of the stacked part 702a, it can be said that the first stack 701 and the stacked part 702a constitute the magnetic field generator 700. The magnetic field generator 700 includes the buffer layer 711, the ferromagnetic layer 712a, the interposing portion 713a, the facing part 714a, and the protective portion 715a.

The MR element 50 and the two yokes 90 are disposed between the two magnetic field generators 700. The two magnetic field generators 700 cooperate to apply bias magnetic fields to the MR element 50 and the two yokes 90. The direction of the magnetization of the ferromagnetic layer 712a of one of the two magnetic field generators 700 may be the same as the direction of the magnetization of the ferromagnetic layer 712a of the other of the two magnetic field generators 700. In this case, the direction of the bias magnetic field generated by one of the two magnetic field generators 700 becomes the same as the direction of the bias magnetic field generated by the other of the two magnetic field generators 700.

If the underlying layer 713 is formed of a same material as the ferromagnetic layer 712a, the ferromagnetic layer 712a and the interposing portion 713a constitute substantially one ferromagnetic layer. The facing part 714a contacts the top surface of this one ferromagnetic layer to be exchange-coupled with this one ferromagnetic layer.

The maximum dimension of the ferromagnetic layer 712a in the stacking direction (direction parallel to the Z direction) of the plurality of magnetic films may be larger than the maximum dimension of the underlying layer 713 in the stacking direction. The maximum dimension of the free layer 54 in the stacking direction is larger than the maximum dimension of the underlying layer 713 in the stacking direction.

The top surface 50a of the MR element 50 and the top surface of each of the two yokes 90 face the non-facing part 714b of the antiferromagnetic layer 714. The distance between the non-facing part 714b and the bottom surface 50b of the MR element 50 is larger than the distance between the top surface 50a and the bottom surface 50b. The distance between the facing part 714a of the antiferromagnetic layer 714 and the top surface of the lower electrode 61 may be the same as the distance between the non-facing part 714b and the bottom surface 50b, or may be different from the distance between the non-facing part 714b and the bottom surface 50b. In the latter case, the maximum distance between the facing part 714a and the top surface of the lower electrode 61 may be larger or smaller than the distance between the non-facing part 714b and the bottom surface 50b.

In the example embodiment, the insulating layer 33 is interposed between the MR element 50 and the two yokes 90, and the two first stacks 701.

The top surface of the second stack 702, i.e., the top surface of the cap layer 715, is in contact with the upper electrode 62. The planar shape of the second stack 702 (shape viewed in the Z direction) may coincide with, may be smaller than, or may be larger than the planar shape of the upper electrode 62.

Heretofore, the configuration of the magnetic field generator 700 has been described with a focus on one MR element 50. In the example embodiment, the magnetic sensor 1 includes the plurality of MR elements 50. As shown in FIG. 17, the plurality of MR elements 50 includes two MR elements 50 arranged along the second direction D2. The second stack 702 is interposed between the two MR elements 50 and the upper electrode 62 electrically connecting the two MR elements 50. In the example shown in FIG. 17, the second stack 702 is disposed on the two MR elements 50, four yokes 90, and four first stacks 701. In this example, the second stack 702 includes four stacked parts 702a.

The two MR elements 50 are electrically connected also by the antiferromagnetic layer 714 of the second stack 702. The two MR elements 50 are connected in series by the antiferromagnetic layer 714.

In the example embodiment, since the magnetic sensor 1 includes the plurality of MR elements 50 and the plurality of magnetic field generators 700, the magnetic sensor 1 includes a plurality of underlying layers 713, a plurality of antiferromagnetic layers 714, and a plurality of cap layers 715.

Next, a method of forming the magnetic field generator 700 in the example embodiment is described. Here, two magnetic field generators 700 will be described with a focus on one MR element 50. As with the first example embodiment, after the two yokes 90 are formed, a photoresist mask is formed on a stacked film that later becomes the MR element 50, on the two yokes 90, and on the insulating layer 32. Next, the photoresist mask is used to pattern the stacked film by etching so that the two side surfaces 50c are formed on the stacked film. In this etching, the two yokes 90 and the insulating layer 32 are also etched. The formation of the two side surfaces 50c on the stacked film causes the stacked film to become the MR element 50. Next, while leaving the photoresist mask in place, the insulating layer 33, the buffer layer 711, and the ferromagnetic layer 712a are formed in order.

Next, the photoresist mask is removed. Next, the underlying layer 713, the antiferromagnetic layer 714, and the cap layer 715 are formed in order over the MR element 50, the two yokes 90, the ferromagnetic layer 712a, and the insulating layer 32. Next, a process of fixing the direction of the magnetization of the ferromagnetic layer 712a is performed. The process of fixing the direction of the magnetization of the ferromagnetic layer 712a is the same as the process of fixing the direction of the magnetization of the ferromagnetic layer 72a in the first example embodiment. The fixation of the direction of the magnetization of the ferromagnetic layer 712a completes the magnetic field generator 700.

Note that the ferromagnetic portion 712 of the magnetic field generator 700 in the example embodiment may include two ferromagnetic layers, as in the fourth and fifth modification examples in the first example embodiment. If the ferromagnetic portion 712 includes two ferromagnetic layers, the magnetic field generator 700 may include a nonmagnetic layer disposed between the two ferromagnetic layers, as in the fifth modification example in the first example embodiment.

The antiferromagnetic portion of the magnetic field generator 700 in the example embodiment may also include, in addition to the facing part 714a, an antiferromagnetic layer disposed between the buffer layer 711 and the ferromagnetic layer 712a, as in the third modification example in the first example embodiment.

The configuration, operation, and effects of the example embodiment are otherwise the same as those of the first example embodiment.

### Modification Examples

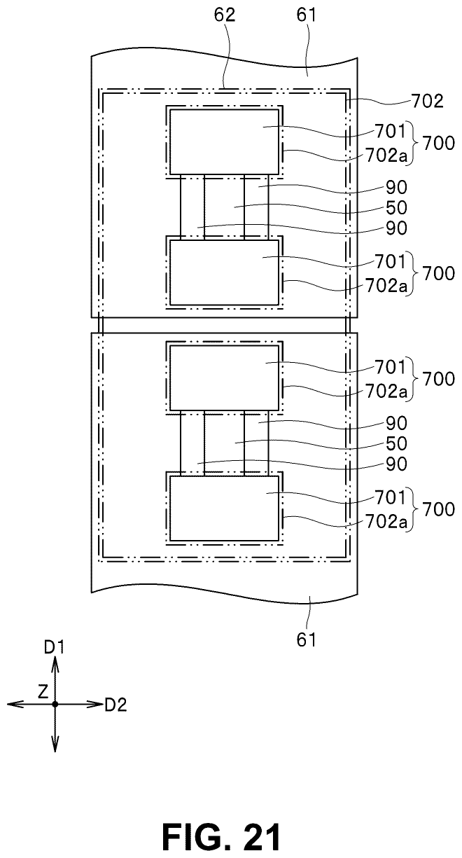

Next, first through third modification examples of the magnetic sensor 1 according to the example embodiment will be described. Initially, the first modification example is described with reference to FIG. 21. FIG. 21 is a plan view showing a main part of the first modification example of the magnetic sensor 1.

In the first modification example, each of the plurality of lower electrodes 61 electrically connects two adjacent MR elements 50 in the first direction D1. Each of the plurality of upper electrodes 62 electrically connects the two adjacent MR elements 50 disposed on the two lower electrodes 61. This connects in series the plurality of MR elements 50 arranged in a row in the first direction D1. In the first modification example, the plurality of connecting electrodes electrically connect the plurality of lower electrodes 61 or the plurality of upper electrodes 62 so that a group of the plurality of MR elements 50 arranged in a row is connected in series.

In the first modification example, the second stack 702 is interposed between the two MR elements 50 arranged in the first direction D1 and the upper electrode 62. The two MR elements 50 are electrically connected also by the antiferromagnetic layer 714 (see FIGS. 18 through 20) of the second stack 702. The two MR elements 50 are connected in series by the antiferromagnetic layer 714.

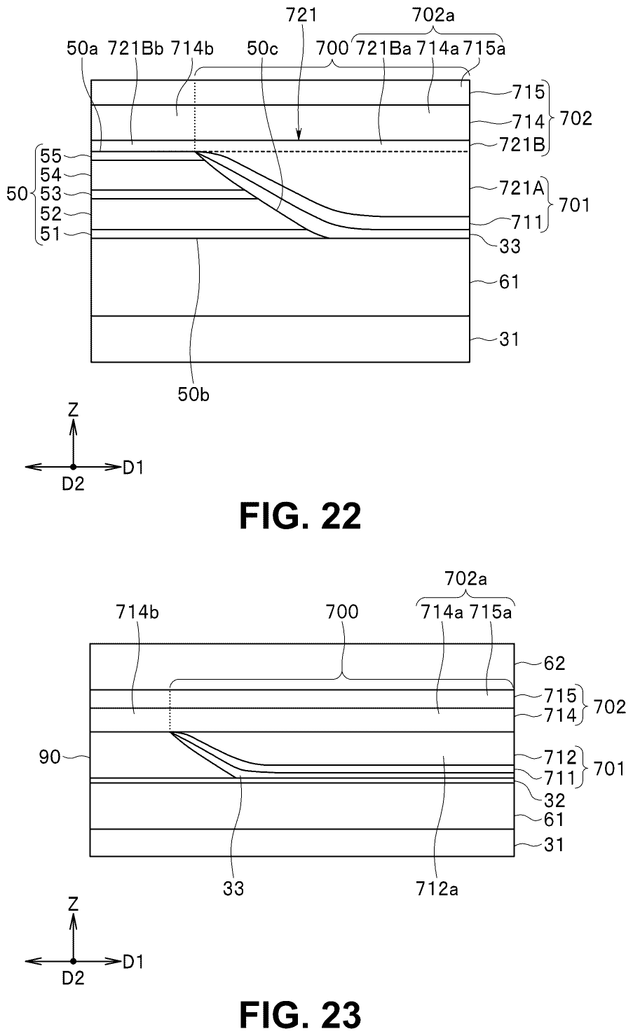

Next, the second modification example will be described with reference to FIG. 22. FIG. 22 is a cross-sectional view showing a main part of the second modification example of the magnetic sensor 1. In the second modification example, the first stack 701 includes, instead of the ferromagnetic layer 712a, a ferromagnetic portion 721A made of a ferromagnetic material. The ferromagnetic portion 721A has the same function as that of the ferromagnetic portion 712. The shape and arrangement of the ferromagnetic portion 721A may be the same as the shape and arrangement of the ferromagnetic layer 712a.

The second stack 702 includes an underlying portion 721B instead of the underlying layer 713. The shape and arrangement of the underlying portion 721B may be the same as the shape and arrangement of the underlying layer 713. The underlying portion 721B includes an interposing portion 721Ba interposed between the ferromagnetic portion 721A and the facing part 714a, and a non-interposing portion 721Bb other than the interposing portion 721Ba. The stacked part 702a includes the interposing portion 721Ba instead of the interposing portion 713a.

In the second modification example in particular, the ferromagnetic portion 721A and the underlying portion 721B are constituted of one ferromagnetic layer 721. In FIG. 22, the boundary between the ferromagnetic portion 721A and the underlying portion 721B is indicated by a dashed line.

Next, the third modification example is described with reference to FIG. 23. FIG. 23 is a cross-sectional view showing a main part of the third modification example of the magnetic sensor 1. In the third modification example, the underlying layer 713 is not provided, and the antiferromagnetic layer 714 is disposed on the MR element 50, the two yokes 90, the two ferromagnetic layers 712a, and the insulating layer 32.

### Third Example Embodiment

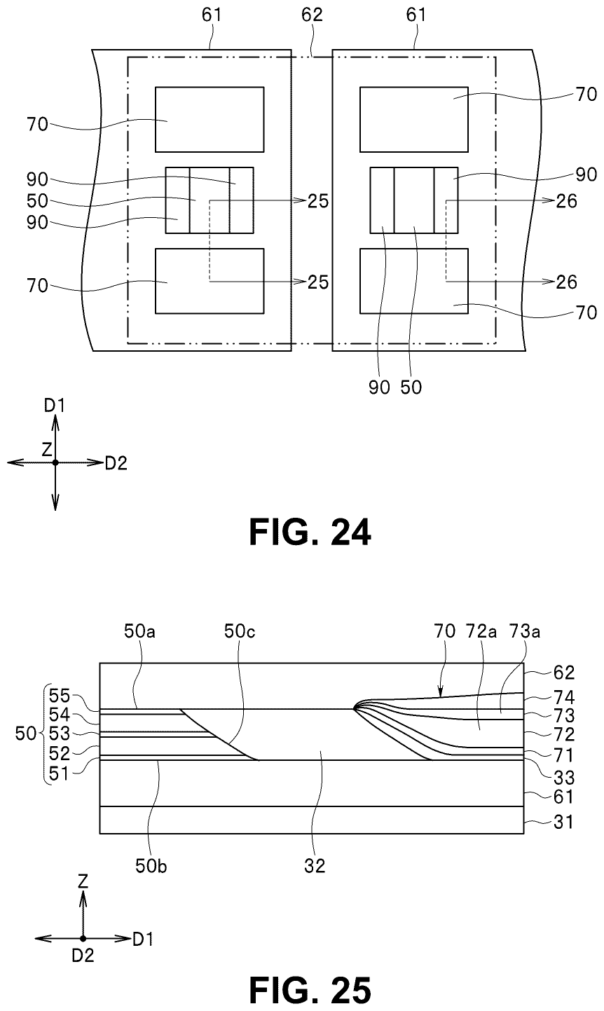

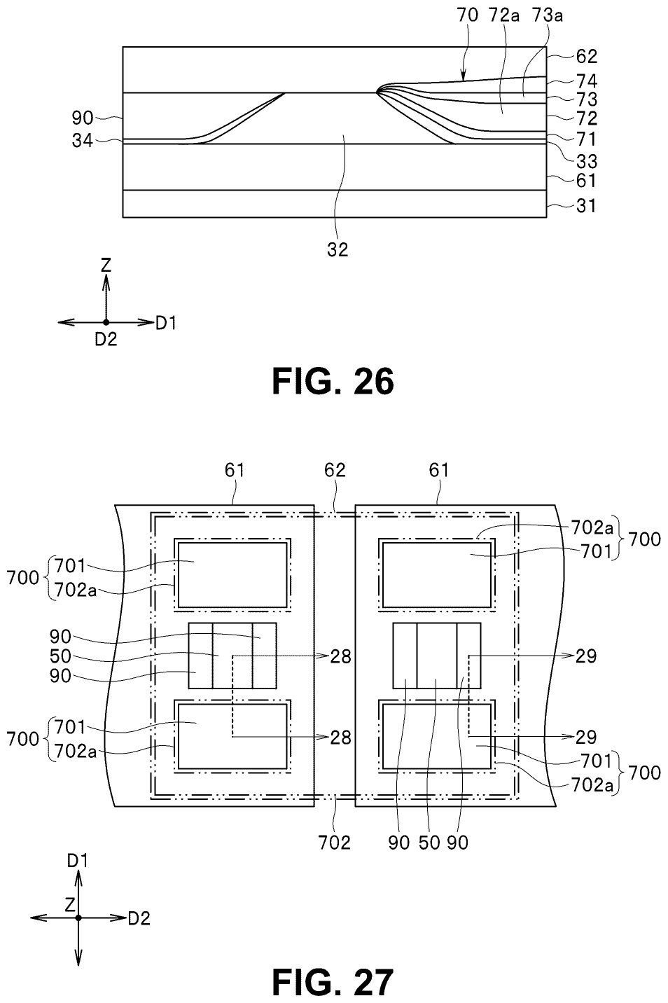

Next, a third example embodiment of the disclosure will be described with reference to FIGS. 24 through 26. FIG. 24 is a plan view showing a main part of a magnetic sensor according to the example embodiment. FIG. 25 is a cross-sectional view showing a part of a cross section at a position indicated by a 25-25 line in FIG. 24. FIG. 26 is a cross-sectional view showing a part of a cross section at a position indicated by a 26-26 line in FIG. 24.

The following describes, with a focus on one MR element 50, how the configuration of the magnetic sensor 1 according to the example embodiment differs from that in the first example embodiment. In the example embodiment, each of the two magnetic field generators 70 is disposed at a distance from the MR element 50. Each of the two magnetic field generators 70 may not overlap the MR element 50 when viewed in the Z direction.

In the example embodiment, each of the two magnetic field generators 70 is disposed at a distance from the two yokes 90. Each of the two magnetic field generators 70 may not overlap the two yokes 90 when viewed in the Z direction.

In the example embodiment, the insulating layer 33 is interposed between the magnetic field generator 70, and the lower electrode 61 and the insulating layer 32. The magnetic sensor 1 according to the example embodiment includes an insulating layer 34 made of an insulating material such as Al₂O₃ or SiO₂ and interposed between the two yokes 90, and the lower electrode 61 and the insulating layer 32.

The configuration, operation, and effects of the example embodiment are otherwise the same as those of the first example embodiment.

### Fourth Example Embodiment

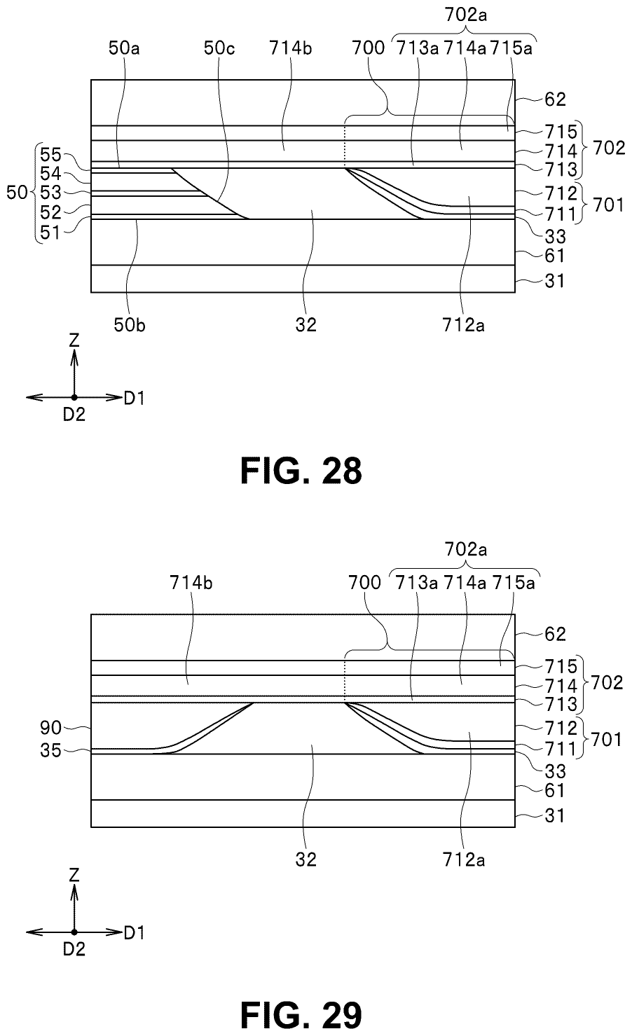

Next, a fourth example embodiment of the disclosure will be described with reference to FIGS. 27 through 29. FIG. 27 is a plan view showing a main part of a magnetic sensor according to the example embodiment. FIG. 28 is a cross-sectional view showing a part of a cross section at a position indicated by a 28-28 line in FIG. 27. FIG. 29 is a cross-sectional view showing a part of a cross section at a position indicated by a 29-29 line in FIG. 27.

The following describes, with a focus on one MR element 50, how the configuration of the magnetic sensor 1 according to the example embodiment differs from that in the second example embodiment. In the example embodiment, each of the two magnetic field generators 700 is disposed at a distance from the MR element 50. Therefore, the ferromagnetic layers 712a of each of the two magnetic field generators 700 is disposed at a distance from the MR element 50. Each of the two magnetic field generators 700 does not overlap the MR element 50 when viewed in the Z direction.

Each of the two magnetic field generators 700 is disposed at a distance from the two yokes 90. Therefore, the ferromagnetic layer 712a of each of the two magnetic field generators 700 is disposed at a distance from the two yokes 90. Each of the two magnetic field generators 700 may not overlap the two yokes 90 when viewed in the Z direction.

In the example embodiment, the insulating layer 33 is interposed between the ferromagnetic layer 712a, and the lower electrode 61 and the insulating layer 32. The magnetic sensor 1 further includes an insulating layer 35 made of an insulating material such as Al₂O₃ or SiO₂ and interposed between the two yokes 90, and the lower electrode 61 and the insulating layer 32.

The configuration, operation, and effects of the example embodiment are otherwise the same as those of the second example embodiment.

### Fifth Example Embodiment

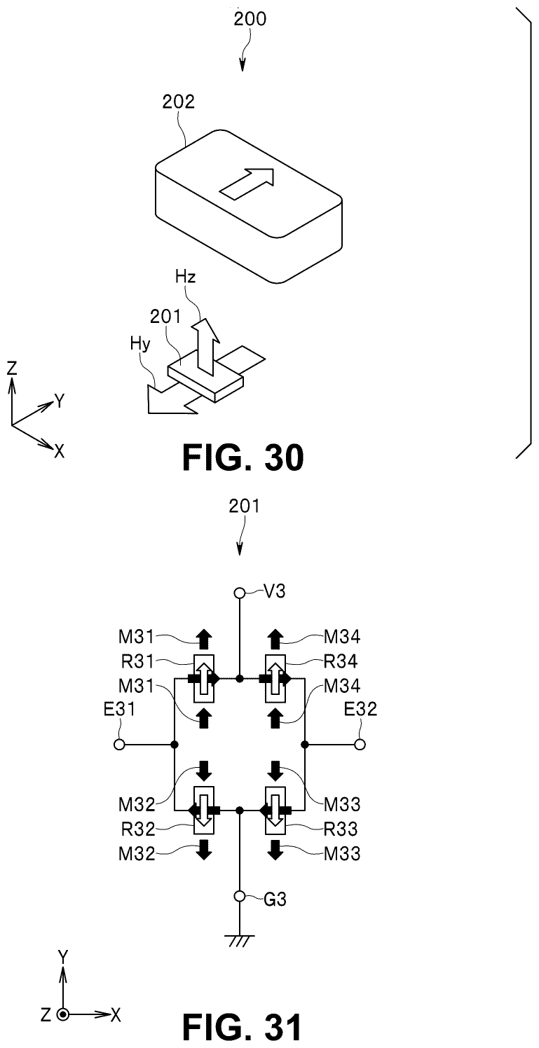

Next, a fifth example embodiment of the disclosure is described. Initially, a configuration of a magnetic sensor system including a magnetic sensor according to the example embodiment is described with reference to FIG. 30. FIG. 30 is a perspective view showing a magnetic sensor system 200 in the example embodiment.

The magnetic sensor system 200 includes a magnetic sensor 201 according to the example embodiment and a magnetic field generation section 202 that generates a predetermined magnetic field. In the example embodiment, the magnetic field generation section 202 is a magnet configured such that a partial magnetic field, which is a part of the generated magnetic field, is applied to the magnetic sensor 201. This partial magnetic field includes a first magnetic field component Hz parallel to the Z direction and a second magnetic field component Hy parallel to the Y direction.

As shown in FIG. 30, in the example embodiment, the direction of the magnetization of the magnetic field generation section 202 is the Y direction, and the direction of the second magnetic field component Hy is the −Y direction. The direction of the first magnetic field component Hz is the Z direction when the magnetic field generation section 202 moves in the Y direction from a predetermined position, and is the −Z direction when the magnetic field generation section 202 moves in the −Y direction from the predetermined position.

Next, a schematic configuration of the magnetic sensor 201 according to the example embodiment is described with reference to FIG. 31. FIG. 31 is a circuit diagram showing a circuit configuration of the magnetic sensor 201.

The magnetic sensor 201 includes four resistor sections R31, R32, R33, and R34, a power supply port V3, a ground port G3, and two output ports E31 and E32. The resistor section R31 is provided between the power supply port V3 and the output port E31. The resistor section R32 is provided between the output port E31 and the ground port G3. The resistor section R33 is provided between the output port E32 and the ground port G3. The resistor section R34 is provided between the power supply port V3 and the output port E32. A voltage or current of a predetermined magnitude is applied to the power supply port V3. The ground port G3 is connected to ground.

Each of the resistor sections R31 to R34 includes the plurality of MR elements 50. The configuration of the plurality of MR elements 50 is the same as that in the first example embodiment. That is, each of the plurality of MR elements 50 includes the buffer layer 51, the magnetization pinned layer 52, the gap layer 53, the free layer 54, and the cap layer 55, as shown in FIGS. 9 and 11 in the first example embodiment.

In FIG. 31, a plurality of solid arrows drawn to overlap the resistor sections R31 to R34, respectively, represent the direction of the magnetization of the magnetization pinned layer 52 in each of the resistor sections R31 to R34. In the example shown in FIG. 31, the direction of the main component of the magnetization of the magnetization pinned layer 52 in each of the resistor sections R31 and R34 is the X direction. The direction of the main component of the magnetization of the magnetization pinned layer 52 in each of the resistor sections R32 and R33 is the −X direction. The free layer 54 in each of the resistor sections R31 to R34 has shape anisotropy in which the direction of the magnetization easy axis is parallel to the Y direction.

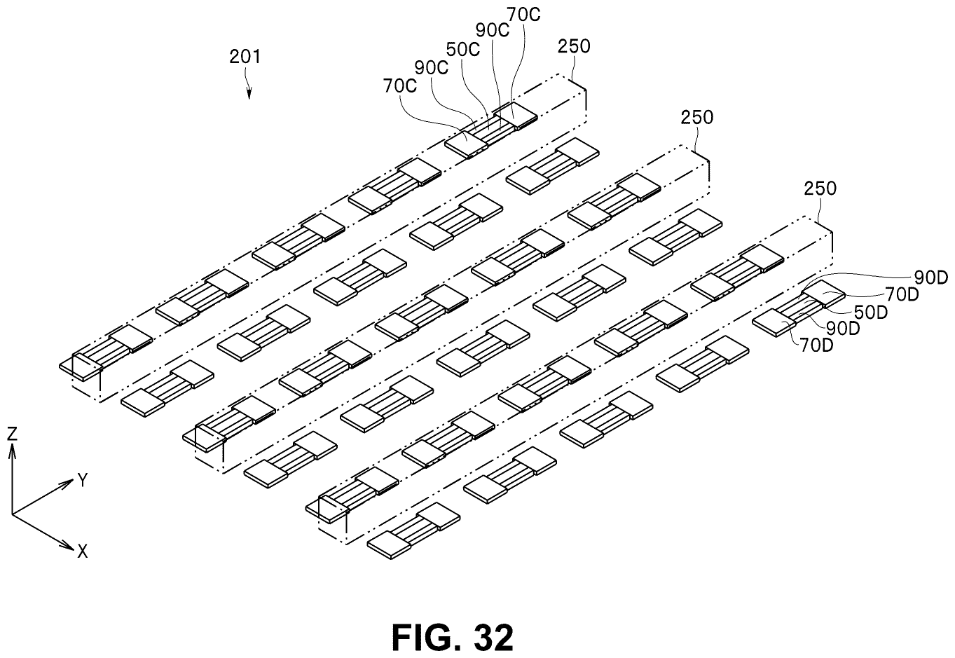

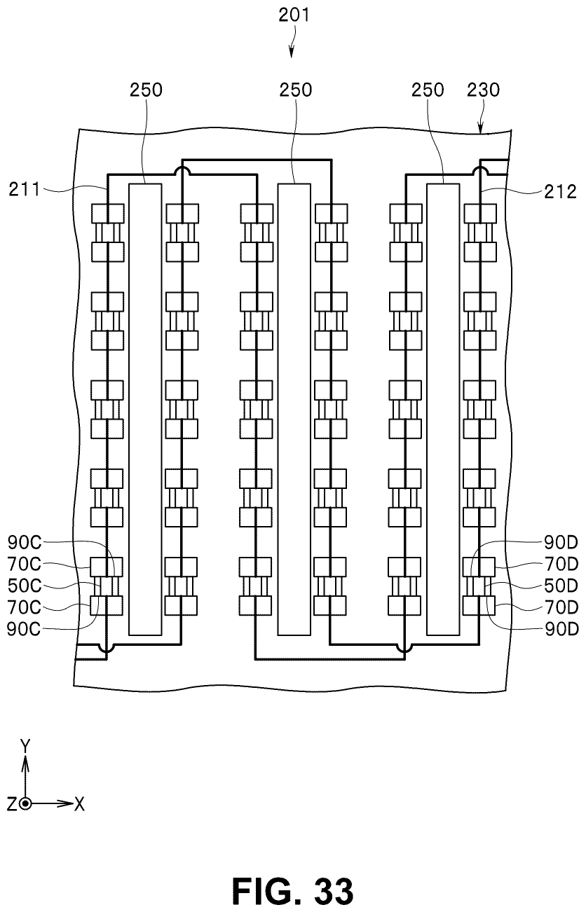

The magnetic sensor 201 further includes the plurality of magnetic field generators 70. The configuration of the plurality of magnetic field generators 70 is the same as in the first example embodiment. Note that the plurality of magnetic field generators 70 are shown in FIGS. 32 and 33, which will be described later.

The plurality of magnetic field generators 70 include a plurality of pairs of the magnetic field generators 70, each pair including two magnetic field generators 70. The two magnetic field generators 70 are disposed at a distance from each other in a direction parallel to the Y direction with one MR element 50 interposed between the two magnetic field generators 70. The two magnetic field generators 70 are configured to apply a bias magnetic field to the one MR element 50 located therebetween. This bias magnetic field includes a component parallel to the Y direction as a main component.

In FIG. 31, arrows labelled with the reference numerals M31, M32, M33, and M34 indicate the directions of the main components of the bias magnetic fields generated by the plurality of magnetic field generators 70 at the resistor sections R31, R32, R33, and R34, respectively. The directions of the main components of the bias magnetic fields at the resistor sections R31 and R34 are each the Y direction. The directions of the main components of the bias magnetic fields at the resistor sections R32 and R33 are each the −Y direction.

In FIG. 31, the plurality of hollow arrows drawn to overlap the resistor sections R31 to R34, respectively, represent the direction of the magnetization of the free layer in each of the resistor sections R31 to R34 in a case where the partial magnetic field is not applied to the magnetic sensor 201. The direction of the main component of the magnetization of the free layer in each of the resistor sections R31 and R34 is the Y direction, and is the same as the direction of the main component of the bias magnetic field at the resistor sections R31 and R34. The direction of the main component of the magnetization of the free layer in each of the resistor sections R32 and R33 is the −Y direction, and is the same as the direction of the main component of the bias magnetic field at the resistor sections R32 and R33.

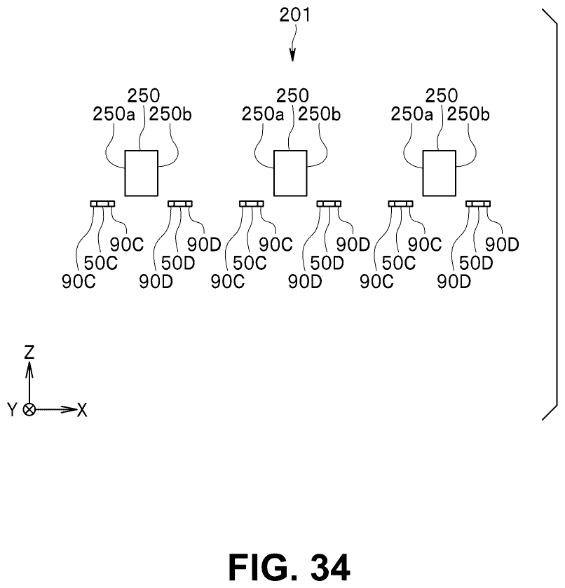

Next, a configuration of the magnetic sensor 201 is specifically described with reference to FIGS. 32 through 34. FIG. 32 is a perspective view showing a part of the magnetic sensor 201. FIG. 33 is a plan view showing the part of the magnetic sensor 201. FIG. 34 is a side view showing the part of the magnetic sensor 201.

The magnetic sensor 201 further includes a substrate 230. The magnetic sensor 201 is constituted by forming a plurality of components other than the substrate 230 on the substrate 230.

The magnetic sensor 201 further includes at least one yoke made of a soft magnetic material. The at least one yoke has a shape long in the Y direction when viewed in the Z direction. The at least one yoke generates a magnetic field component in a direction parallel to the X direction based on the first magnetic field component Hz shown in FIG. 30.

As shown in FIGS. 32 through 34, in the example embodiment in particular, the magnetic sensor 201 includes, as the at least one yoke, a plurality of yokes 250 disposed to be arranged in the X direction. Each of the plurality of yokes 250 has, for example, a rectangular parallelepiped shape long in the Y direction. The plurality of yokes 250 have a same shape. Each of the plurality of yokes 250 has a first end surface 250a and a second end surface 250b located at both ends in a direction parallel to the X direction. In each of the plurality of yokes 250, the first end surface 250a is located at an end in the −X direction and the second end surface 250b is located at an end in the X direction.

Each of the plurality of MR elements 50 is disposed at a position where a magnetic field component generated by the plurality of yokes 250 is applied thereto. In the example embodiment in particular, each of the MR elements 50 is disposed in the vicinity of an end portion of each of the plurality of yokes 250 in the −Z direction. The plurality of MR elements 50 are disposed such that a group of the plurality of MR elements 50 are arranged along the first end surface 250a or the second end surface 250b of each of the plurality of yokes 250. Hereinafter, of the plurality of MR elements 50, a plurality of MR elements arranged along the first end surface 250a are denoted by the reference numeral 50C, and the plurality of MR elements arranged along the second end surface 250b are denoted by the reference numeral 50D. The direction of the magnetic field component received by the plurality of MR elements 50C and the direction of the magnetic field component received by the plurality of MR elements 50D are opposite to each other.

The plurality of MR elements 50C and the plurality of MR elements 50D may or may not overlap the plurality of yokes 250 when viewed in the Z direction. In the examples shown in FIGS. 32 through 34, the plurality of MR elements 50C and the plurality of MR elements 50D are disposed so as not to overlap the plurality of yokes 250 when viewed in the Z direction.

As previously mentioned, the magnetic sensor 201 includes the plurality of magnetic field generators 70. As shown in FIGS. 32 and 33, of the plurality of magnetic field generators 70, a plurality of magnetic field generators disposed with the MR element 50C interposed therebetween is denoted by the reference numeral 70C, and a plurality of magnetic field generators disposed with the MR element 50D interposed therebetween is denoted by the reference numeral 70D.

The magnetic sensor 201 further includes the plurality of yokes 90. The configuration of the plurality of yokes 90 is the same as in the first example embodiment. As shown in FIGS. 32 and 33, of the plurality of yokes 90, a plurality of yokes disposed with the MR element 50C interposed therebetween is denoted by the reference numeral 90C, and a plurality of yokes disposed with the MR element 50D interposed therebetween is denoted by the reference numeral 90D.

The plurality of yokes 90C have a function of guiding magnetic field components generated by the plurality of yokes 250 to the plurality of MR elements 50C. The plurality of yokes 90D have a function of guiding the magnetic field components generated by the plurality of yokes 250 to the plurality of MR elements 50D.

The magnetic sensor 201 further includes a wiring portion 211 electrically connecting the plurality of MR elements 50C and a wiring portion 212 electrically connecting the plurality of MR elements 50D. Each of the wiring portions 211 and 212 is constituted of the plurality of lower electrodes 61 and the plurality of upper electrodes 62, and the plurality of connecting electrodes, which were described in the first example embodiment.

The wiring portion 211 includes a first wiring electrically connecting the plurality of MR elements 50C in which the direction of the main component of the magnetization of the magnetization pinned layer 52 is the X direction, and a second wiring electrically connecting the plurality of MR elements 50C in which the direction of the main component of the magnetization of the magnetization pinned layer 52 is the −X direction. The resistor section R31 is constituted of the plurality of MR elements 50C electrically connected by the first wiring. The resistor section R32 is constituted of the plurality of MR elements 50C electrically connected by the second wiring.

The wiring portion 212 includes a third wiring electrically connecting the plurality of MR elements 50D in which the direction of the main component of the magnetization of the each magnetization pinned layer 52 is the −X direction, and a fourth wiring electrically connecting the plurality of MR elements 50D in which the direction of the main component of the magnetization of the each magnetization pinned layer 52 is the X direction. The resistor section R33 is constituted of the plurality of MR elements 50D electrically connected by the third wiring. The resistor section R34 is constituted of the plurality of MR elements 50D electrically connected by the fourth wiring.

Next, an operation of the magnetic sensor 201 is described. In a state where a first magnetic field component Hz is not present and consequently magnetic field components generated by the plurality of yokes 250 are also not present, the direction of the magnetization of the free layer 54 of each of the plurality of MR elements 50C and the plurality of MR elements 50D is a direction parallel to the Y direction.

When the direction of the first magnetic field component Hz is the Z direction, the direction of the magnetic field component received by each of the plurality of MR elements 50C constituting the resistor sections R31 and R32 is the X direction, and the direction of the magnetic field component received by each of the plurality of MR elements 50D constituting the resistor sections R33 and R34 is the −X direction. In this case, the direction of the magnetization of the free layer 54 of each of the plurality of MR elements 50C inclines from a direction parallel to the Y direction toward the X direction, and the direction of the magnetization of the free layer 54 of each of the plurality of MR elements 50D inclines from a direction parallel to the Y direction toward the −X direction. As a result, compared to a state in which no magnetic field component is present, the resistance value of each of the plurality of MR elements 50C constituting the resistor section R31 and the resistance value of each of the plurality of MR elements 50D constituting the resistor section R33 decrease, and the resistance value of each of the plurality of MR elements 50C constituting the resistor section R32 and the resistance value of each of the plurality of MR elements 50D constituting the resistor section R34 increase. As a result, the resistance values of the resistor sections R31 and R33 decrease and the resistance values of the resistor sections R32 and R34 increase.

If the direction of the first magnetic field component Hz is the −Z direction, the direction of the magnetic field component and the change in the resistance value of each of the resistor sections R31 to R34 are opposite to the above-mentioned case where the direction of the first magnetic field component Hz is the Z direction.

The amount of change in the resistance value of each of the resistor sections R31 to R34 depends on the strength of the magnetic field component received by each of the plurality of MR elements 50C and the plurality of MR elements 50D. When the strength of the magnetic field component increases, the resistance value of each of the resistor sections R31 to R34 changes such that the amount of increase or the amount of decrease of the resistance value becomes larger. When the strength of the magnetic field component becomes smaller, the resistance value of each of the resistor sections R31 to R34 changes such that the amount of increase or the amount of decrease of the resistance value becomes smaller. The strength of the magnetic field component depends on the strength of the first magnetic field component Hz.

Thus, when the direction and strength of the first magnetic field component Hz change, the resistance value of each of the resistor sections R31 to R34 changes such that either the resistance value of each of the resistor sections R31 and R33 increases and the resistance value of each of the resistor sections R32 and R34 decreases, or the resistance value of each of the resistor sections R31 and R33 decreases and the resistance value of each of the resistor sections R32 and R34 increases. This changes the potential of the connection point between the resistor sections R31 and R32, i.e., the potential of the output port E31, and the potential of the connection point between the resistor sections R33 and R34, i.e., the potential of the output port E32. The magnetic sensor 201 may generate a signal corresponding to the potential of the output port E31 and a signal corresponding to the potential of the output port E32, each as a detection signal. Alternatively, the magnetic sensor 201 may generate a signal corresponding to the potential difference between the output ports E31 and E32 as a detection signal. In this case, the magnetic sensor 201 may further include a differential amplifier (difference detector) that outputs the signal corresponding to the potential difference between the output ports E31 and E32 as a detection signal.

The magnetic sensor system 200 may further include the processor 2 shown in FIGS. 1 and 2 in the first example embodiment. The processor 2 may be configured to receive one detection signal or two detection signals output from the magnetic sensor 201 to generate a detection value having a correspondence with the strength of the first magnetic field component Hz or a detection value having a correspondence with the position of the magnetic field generation section 202 (see FIG. 30).

Note that the magnetic sensor 201 according to the example embodiment may include the plurality of magnetic field generators 700 in the second example embodiment, instead of the plurality of magnetic field generators 70. The configuration, operation, and effects of the example embodiment are otherwise the same as those of the first or second example embodiment.

Note that the disclosure is not limited to the foregoing example embodiments, and various modifications may be made thereto. For example, the magnetic sensor of the disclosure may be a magnetic sensor including the first and second detection circuits 10 and 20 in the first example embodiment, and the magnetic sensor 201 according to the fifth example embodiment as a third detection circuit. In this magnetic sensor, the third detection circuit (magnetic sensor 201) may be configured to detect a component in a direction parallel to the Z direction of the target magnetic field. This magnetic sensor may be a geomagnetic sensor that detects the geomagnetism as the target magnetic field.

The MR element 50 may be constituted of the buffer layer 51, the free layer 54, the gap layer 53, the magnetization pinned layer 52, and the cap layer 55 stacked in this order from the lower electrode 61 side.

The one MR element 50 and the two yokes 90 adjacent to this one MR element 50 may be disposed between two first magnetic field generators and two second magnetic field generators in the first direction D1. The two first magnetic field generators are disposed at a distance from each other in the second direction D2. Similarly, the two second magnetic field generators are disposed at a distance from each other in the second direction D2. The two first magnetic field generators each overlap the two yokes 90 when viewed in the first direction D1. Similarly, the two second magnetic field generators each overlap the two yokes 90 when viewed in the first direction D1. The two first magnetic field generators and the two second magnetic field generators may or may not overlap the MR element 50 when viewed in the first direction D1.

As described above, a magnetic sensor according to one embodiment of the disclosure includes: a magnetoresistive element; at least one yoke including a magnetic layer made of a soft magnetic material, the at least one yoke being adjacent to the magnetoresistive element and spaced at a distance apart from each other; and at least one magnetic field generator including a ferromagnetic portion made of a ferromagnetic material and an antiferromagnetic portion made of an antiferromagnetic material and exchange-coupled with the ferromagnetic portion, the at least one magnetic field generator being configured to generate a magnetic field to be applied to the at least one yoke.

In the magnetic sensor according to one embodiment of the disclosure, the at least one magnetic field generator may include two magnetic field generators. The magnetoresistive element and the at least one yoke may be disposed between the two magnetic field generators.

In the magnetic sensor according to one embodiment of the disclosure, the at least one yoke may include two yokes. The magnetoresistive element may be disposed between the two yokes.

In the magnetic sensor according to one embodiment of the disclosure, the magnetic field generated by the at least one magnetic field generator may be applied to the magnetoresistive element.

In the magnetic sensor according to one embodiment of the disclosure, a part of the at least one magnetic field generator may overlap the at least one yoke when viewed in an orthogonal direction orthogonal to a direction in which the magnetoresistive element and the at least one yoke are arranged.

In the magnetic sensor according to one embodiment of the disclosure, the ferromagnetic portion may include a ferromagnetic layer made of a ferromagnetic material, the ferromagnetic layer being disposed so that a part of the ferromagnetic layer overlaps the at least one yoke when viewed in a direction orthogonal to a direction in which the magnetoresistive element and the at least one yoke are arranged. The antiferromagnetic portion may include an antiferromagnetic made of an antiferromagnetic material, the antiferromagnetic layer being in contact with the ferromagnetic layer.

In the magnetic sensor according to one embodiment of the disclosure, the ferromagnetic portion may include a ferromagnetic layer made of a ferromagnetic material, the ferromagnetic layer being disposed so that a part of the ferromagnetic layer overlaps the at least one yoke when viewed in a direction orthogonal to a direction in which the magnetoresistive element and the at least one yoke are arranged. The magnetic sensor according to one embodiment of the disclosure may further include an antiferromagnetic layer made of an antiferromagnetic material, the antiferromagnetic layer being disposed over the magnetoresistive element, the at least one yoke, and the ferromagnetic layer. The antiferromagnetic layer may further include a facing part that faces the ferromagnetic layer and a non-facing part that faces the magnetoresistive element and the at least one yoke but does not face the ferromagnetic layer. The antiferromagnetic portion may include the facing part. The magnetic sensor according to one embodiment of the disclosure further includes an underlying layer interposed between the ferromagnetic layer and the antiferromagnetic layer.

The magnetic sensor according to one embodiment of the disclosure further includes a lower electrode and an upper electrode each made of a conductive material. The magnetoresistive element may be disposed on the lower electrode. The upper electrode may be disposed on the magnetoresistive element, the at least one yoke, and the at least one magnetic field generator.

In the magnetic sensor according to one embodiment of the disclosure, the magnetoresistive element may include a plurality of magnetic films stacked together. A part of the at least one magnetic field generator may overlap a part of the at least one yoke when viewed in a stacking direction of the plurality of magnetic films. Alternatively, the at least one magnetic field generator may not overlap the at least one yoke when viewed in the stacking direction of the plurality of magnetic films.

The magnetic sensor according to one embodiment of the disclosure further includes a plurality of resistor sections each including the magnetoresistive element. The at least one yoke includes a plurality of yokes. The at least one magnetic field generator may include a plurality of magnetic field generators. Each of the plurality of yokes may be adjacent to the magnetoresistive element of one of the plurality of resistor sections. Each of the plurality of magnetic field generators may be configured such that the magnetic field is applied to one of the plurality of yokes. The plurality of magnetic field generators may include a first specific magnetic field generator in which a direction of the magnetic field is a first direction and a second specific magnetic field generator in which a direction of the magnetic field is a second direction.

In the magnetic sensor of the disclosure, at least one magnetic field generator includes a ferromagnetic portion made of a ferromagnetic material and an antiferromagnetic portion that is made of an antiferromagnetic material and that is to be exchange-coupled with the ferromagnetic portion, and is configured to generate a magnetic field to be applied to at least one yoke. According to this disclosure, this enable to apply a stable bias magnetic field to the yokes.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. A magnetic sensor comprising:
a magnetoresistive element;
at least one yoke including a magnetic layer made of a soft magnetic material, the at least one yoke being adjacent to the magnetoresistive element and spaced at a distance apart from each other; and
at least one magnetic field generator including a ferromagnetic portion made of a ferromagnetic material and an antiferromagnetic portion made of an antiferromagnetic material and exchange-coupled with the ferromagnetic portion, the at least one magnetic field generator being configured to generate a magnetic field to be applied to the at least one yoke.

2. The magnetic sensor according to claim 1, wherein
the at least one magnetic field generator comprises two magnetic field generators, and
the magnetoresistive element and the at least one yoke are disposed between the two magnetic field generators.

3. The magnetic sensor according to claim 1, wherein
the at least one yoke comprises two yokes, and
the magnetoresistive element is disposed between the two yokes.

4. The magnetic sensor according to claim 1, wherein the magnetic field generated by the at least one magnetic field generator is applied to the magnetoresistive element.

5. The magnetic sensor according to claim 1, wherein a part of the at least one magnetic field generator overlaps the at least one yoke when viewed in an orthogonal direction orthogonal to a direction in which the magnetoresistive element and the at least one yoke are arranged.

6. The magnetic sensor according to claim 1, wherein
the ferromagnetic portion includes a ferromagnetic layer made of a ferromagnetic material, the ferromagnetic layer being disposed so that a part the ferromagnetic layer overlaps the at least one yoke when viewed in a direction orthogonal to a direction in which the magnetoresistive element and the at least one yoke are arranged, and
the antiferromagnetic portion includes an antiferromagnetic layer made of an antiferromagnetic material, the antiferromagnetic layer being in contact with the ferromagnetic layer.

7. The magnetic sensor according to claim 1, wherein
the ferromagnetic portion includes a ferromagnetic layer made of a ferromagnetic material, the ferromagnetic layer being disposed so that a part of the ferromagnetic layer overlaps the at least one yoke when viewed in a direction orthogonal to a direction in which the magnetoresistive element and the at least one yoke are arranged,
the magnetic sensor further comprises an antiferromagnetic layer made of an antiferromagnetic material, the antiferromagnetic layer being disposed over the magnetoresistive element, the at least one yoke, and the ferromagnetic layer,
the antiferromagnetic layer includes a facing part that faces the ferromagnetic layer and a non-facing part that faces the magnetoresistive element and the at least one yoke but does not face the ferromagnetic layer, and
the antiferromagnetic portion includes the facing part.

8. The magnetic sensor according to claim 7, further comprising:
an underlying layer interposed between the ferromagnetic layer and the antiferromagnetic layer.

9. The magnetic sensor according to claim 1, further comprising:
a lower electrode and an upper electrode each made of a conductive material, wherein
the magnetoresistive element is disposed on the lower electrode, and
the upper electrode is disposed on the magnetoresistive element, the at least one yoke, and the at least one magnetic field generator.

10. The magnetic sensor according to claim 1, wherein
the magnetoresistive element includes a plurality of magnetic films stacked together, and
a part of the at least one magnetic field generator overlaps a part of the at least one yoke when viewed in a stacking direction of the plurality of magnetic films.

11. The magnetic sensor according to claim 1, wherein
the magnetoresistive element includes a plurality of magnetic films stacked together, and
the at least one magnetic field generator does not overlap the at least one yoke when viewed in a stacking direction of the plurality of magnetic films.

12. The magnetic sensor according to claim 1, further comprising:
a plurality of resistor sections each including the magnetoresistive element, wherein
the at least one yoke comprises a plurality of yokes,
the at least one magnetic field generator comprises a plurality of magnetic field generators,
each of the plurality of yokes is adjacent to the magnetoresistive element of one of the plurality of resistor sections,
each of the plurality of magnetic field generators is configured such that the magnetic field is applied to one of the plurality of yokes, and
the plurality of magnetic field generators include a first specific magnetic field generator in which a direction of the magnetic field is a first direction and a second specific magnetic field generator in which a direction of the magnetic field is a second direction.
